(19) United States
(12) Patent Application Publication
(10) Pub. No.: US 2008/0199976 A1
(43) Pub. Date: Aug. 21, 2008

(54) METHOD OF MANUFACTURING SEMICONDUCTOR DEVICE INCLUDING FERROELECTRIC CAPACITOR

(75) Inventors: Takahiro YAMAGATA, Kawasaki (JP); Kouichi NAGAI, Kawasaki (JP); Junichi WATANABE, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/035,066

(22) Filed: Feb. 21, 2008

(30) Foreign Application Priority Data
Feb. 21, 2007 (JP) 2007-040351

(51) Int. Cl. H01L 21/8239

(52) U.S. Cl. 438/3; 257/E21.011; 257/E21.645

(57) ABSTRACT

A semiconductor device manufacturing method has a step forming a transistor layer portion on a semiconductor substrate, and a step forming a ferroelectric capacitor portion including a lower electrode, a ferroelectric substance and an upper electrode above the transistor layer portion, wherein the step forming the ferroelectric capacitor portion includes adjusting an area of the upper electrode on the basis of manufacturing parameters of the ferroelectric capacitor portion.

This application claims the benefit of Japanese Patent Application No. 2007-040351 filed on Feb. 21, 2007 in the Japanese Patent Office, the disclosure of which is herein incorporated in its entirety by reference.

### BACKGROUND

This application relates to a semiconductor device including a ferroelectric capacitor and to a manufacturing method thereof.

Over the recent years, there has been advanced the development of a ferroelectric memory (FeRAM: Ferroelectric Random Access Memory) in which a ferroelectric capacitor retains information by utilizing reversal of polarization of a ferroelectric substance. The ferroelectric memory is a nonvolatile memory in which the retained information does not get volatile even when switching off a power supply, and is focused especially in terms of enabling realization of high integration, high-speed drive, high durability and low power consumption.

A main material of a ferroelectric film building up the ferroelectric capacitor involves using a ferroelectric oxide having a perovskite crystalline structure such as a PZT (Pb(Zr, Ti)O₃) film and an SBT (SrBi₂Ta₂O₉) film, which are on the order of 10-30 μC/cm2 and have a large residual polarization quantity.

Generally, a large residual polarization quantity strengthens durability against a damage caused by plasma, a gas and heat when forming multi-layered wiring, which is called process deterioration after forming the ferroelectric capacitor. Further, a margin for a change in temperature (particularly on the higher temperature side) after writing is improved. Therefore, the semiconductor device has hitherto been manufactured with a contrivance of increasing the residual polarization quantity to the greatest possible degree.

Even if there is the residual polarization quantity to some extent at point of time when a bit 1 is written to the ferroelectric capacitor at a normal temperature and when the ferroelectric capacitor reaches a high temperature of approximately 90° C.-250° C., the residual polarization quantity decreases due to the heat. This phenomenon is called thermal depolarization. Accordingly, if the residual polarization quantity is small at an early stage, the residual polarization might disappear because of being disabled to endure the thermal depolarization. Alternatively, the residual component gets small enough not to distinguish between “0” and “1”.

The conventional technology is a general type of technique of increasing the residual polarization quantity as much as possible. For example, a method of providing the ferroelectric capacitor for evaluating characteristics, measuring the characteristics of the ferroelectric capacitor in the course of a semiconductor device manufacturing process, and determining a way of how the subsequent processes proceed corresponding to a result of the measurement was proposed.

### SUMMARY

According to a certain aspect of the embodiments of the present invention, a semiconductor device manufacturing method is provided that comprises: forming a transistor layer portion on a semiconductor substrate; and forming a ferroelectric capacitor portion including a lower electrode, a ferroelectric substance and an upper electrode above the transistor layer portion, wherein the forming the ferroelectric capacitor portion includes adjusting an area of the upper electrode on the basis of manufacturing parameters of the ferroelectric capacitor portion.

### BRIEF DESCRIPTION OF THE DRAWINGS

FIG. 1 is a diagram illustrating an outline of a semiconductor device manufacturing process according to one embodiment of the present invention;

FIG. 2A is a diagram illustrating input power to a sputtering apparatus when conducting the film formation by sputtering and an orientation of the formed lower electrode;

FIG. 2B is a diagram illustrating a half-value width of an intensity distribution (a rocking curve) of X-ray diffraction;

FIG. 2C is a diagram illustrating an argon gas flow rate when conducting the film formation by sputtering and the orientation of the formed lower electrode;

FIG. 2D is a diagram illustrating a half-value width of the intensity distribution (the rocking curve) of the X-ray diffraction;

FIG. 2E is a diagram illustrating the orientation of the lower electrode in a case where the electric power and the argon gas flow rate when conducting the film formation by sputtering take reference values, and the orientation of the lower electrode when under a condition of such a combination as to improve the orientation;

FIG. 2F is a diagram illustrating a half-value width of the intensity distribution (the rocking curve) of the X-ray diffraction;

FIG. 2G is a diagram illustrating, when controlling a <222> orientation of the lower electrode, an orientation ratio of the ferroelectric substance (PZT) formed on an upper portion thereof;

FIG. 2H is a diagram showing an orientation ratio of the ferroelectric substance (PZT);

FIG. 2I is a diagram illustrating a relationship between a temperature when forming the film and the <222> orientation;

FIG. 2J is a diagram illustrating a half-value width of the intensity distribution (the rocking curve) of the X-ray diffraction;

FIG. 2K is a diagram showing a relationship between the orientation of the ferroelectric substance (PZT) and a residual polarization quantity of a ferroelectric capacitor in which PZT is used as the ferroelectric substance;

FIG. 2L is a diagram showing a relationship between a <100> orientation and a <111> orientation in the same sample of the ferroelectric substance (PZT);

FIG. 3A is a diagram a relationship between a crystallization annealing temperature when producing PZT crystal and the residual polarization quantity of an FeRAM containing the PZT generated by the crystallization anneal in a way that fixes a relative lead quantity in the PZT;

FIG. 3B is a diagram illustrating a relationship between a crystallization annealing temperature when producing PZT crystal and the residual polarization quantity of an FeFAM containing the PZT generated by the crystallization anneal in a way that fixes a reflectance of the upper electrode;

FIG. 3C is a diagram illustrating sensitivities according to quality engineering as degrees of influence of the PZT crystallization annealing temperature upon the residual polarization quantity;

FIG. 4A is a diagram illustrating a relationship between the relative lead quantity in the PZT crystal and the residual polarization quantity of the FeRAM containing the PZT in a way that fixes the PZT crystallization annealing temperature;

FIG. 4B is a diagram illustrating a relationship between the relative lead quantity in the PZT crystal and the residual polarization quantity of the FeRAM containing the PZT in a way that fixes the reflectance of the upper electrode;

FIG. 4C is a diagram illustrating the sensitivities according to the quality engineering as degrees of influence of the relative lead quantity in the PZT upon the residual polarization quantity;

FIG. 5A is a diagram illustrating a relationship between the light reflectance of the upper electrode and the residual polarization quantity of the FeRAM containing the upper electrode in a way that fixes the relative lead quantity in the PZT;

FIG. 5B is a diagram showing a relationship between the light reflectance of the upper electrode and the residual polarization quantity of the FeRAM containing the upper electrode in a way that fixes the PZT crystallization annealing temperature;

FIG. 6 is a diagram illustrating the residual polarization quantity with respect to a case of conducting recovery anneal at different temperatures;

FIG. 7A is a diagram illustrating a relationship between a film thickness of the PZT and the residual polarization quantity;

FIG. 7B is a diagram illustrating a relationship between an oxygen flow rate and the residual polarization quantity when in the crystallizing anneal;

FIG. 8A is a diagram illustrating a relationship between a film thickness of the upper electrode and the residual polarization quantity of a ferroelectric substance formed under the upper electrode;

FIG. 8B is a diagram illustrating a relationship between the crystallization annealing temperature of the upper electrode and the residual polarization quantity of the ferroelectric substance formed under the upper electrode;

FIG. 9 is a view illustrating a process 1 (formation of a transistor layer) of a planar type capacitor manufacturing flow;

FIG. 10A is a view illustrating a process 2 (formation of an inter-layer film);

FIG. 10B is a view illustrating a process 2B (formation of an ALO film);

FIG. 11 is a view illustrating a process 3 (formation of a pattern of the upper electrode);

FIG. 12A is a view illustrating a process 4A (formation of the pattern of the upper electrode);

FIG. 12B is a view illustrating g a process 4B (a pattern of the ferroelectric substance, a section of the upper electrode pattern);

FIG. 12C is a view illustrating a process 4C (the pattern of the ferroelectric substance, an upper face of the upper electrode pattern);

FIG. 13A is a view illustrating a process 5A (formation of the inter-layer film);

FIG. 13B is a view illustrating a process 5B (a top view of the upper electrode pattern);

FIG. 14 is a view illustrating a process 6 (enlarged view of the capacitor);

FIG. 15 is a view illustrating a process 7 (formation of a contact hole);

FIG. 16A is a view illustrating a process 8A (formation of a W plug for a transistor);

FIG. 16B is a view illustrating a process 8B (formation of the W plug for the capacitor)

FIG. 17A is a view illustrating a process 9A (removal of a P-SiON film);

FIG. 17B is a view illustrating a process 9B (film formation of a first wiring layer);

FIG. 18 is a view illustrating a process 10 (patterning of the first wiring layer);

FIG. 19 is a view illustrating a process 11 (formation of the inter-layer film);

FIG. 20A is a view illustrating a process 12A (formation of the contact hole);

FIG. 20B is a view illustrating a process 12B (formation of the w plug);

FIG. 21 is a view illustrating a process 13 (film formation of a second wiring layer);

FIG. 22 is a view illustrating a process 14 (patterning of the second wiring layer, formation of the inter-layer film);

FIG. 23 is a view illustrating a process 15 (formation of the contact hole);

FIG. 24 is a view illustrating a process 16 (formation of the W plug);

FIG. 25 is a view illustrating a process 17 (film formation of a third wiring layer);

FIG. 26 is a view illustrating a process 18 (patterning of the second wiring layer);

FIG. 27 is a view illustrating a process 19 (formation of P-SiN film);

FIG. 28A is a view showing a process 20A (formation of a protection film, top view);

FIG. 28B is a view showing a process 20B (formation of the protection film);

FIG. 29 is a view showing a stack type capacitor manufacturing process (TiN film−TEOS film);

FIG. 30 is a view showing a manufacturing process (formation of TEOS film−resist);

FIG. 31 is a view showing a manufacturing process (etching of the TEOS film);

FIG. 32 is a view showing a manufacturing process (etching of the TiN film);

FIG. 33 is a view showing a manufacturing process (etching of the ferroelectric substance);

FIG. 34 is a view showing a manufacturing process (peeling of the TiN film);

FIG. 35 is a view showing a manufacturing process (sputtering of ALO film−formation of inter-layer insulating film);

FIG. 36 is a view showing a manufacturing process (formation of the contact hole);

FIG. 37 is a view showing a manufacturing process (formation of the W plug);

### DETAILED DESCRIPTION

The residual polarization quantity has been considered more preferable as it becomes higher, and hence the manufacturing method and conditions have been contrived so as to increase the residual polarization quantity to the greatest possible degree.

A recent research, however, reveals that if the residual polarization quantity of the device exceeds a fluctuation range of a predicted residual polarization quantity set by a design circuit at the early stage, the result obtained is such that the circuit does not function well on the contrary, or alternatively the reliability declines from a long-term viewpoint. For example, if the residual polarization quantity is set too high, a capacitance of the ferroelectric capacitor portion rises, and hence it is difficult to be charged with electric charges within a predetermined period of time. As a result, a speed of accessing the element including this type of ferroelectric capacitor decreases. Thus, if the residual polarization quantity is set too high, the circuit operation loses a balance, and a failure of the operation is induced. While on the other hand, if the residual polarization quantity is set too low, the residual polarization quantity becomes small due to the thermal depolarization, and consequently the circuit side is unable to determine which value, “0” or “1”, is recorded. Thus, the residual polarization quantity affects the circuit operation either when too high or when too low. Further, as a matter of course, if there is a large fluctuation in the capacity of the residual polarization quantity within the same element, this fluctuation causes a fault in the circuit operation. The technologies embrace a method of measuring the residual polarization quantity in a wiring process and a method of determining the way of how the subsequent processes proceed by measuring the ferroelectric capacitor provided for monitoring. Any technologies, however, did not make a proposal of specifically controlling the residual polarization quantity.

A method of manufacturing a semiconductor device according to a best mode (which will hereinafter be termed an embodiment) will hereinafter be described with reference to the drawings. A configuration in the following embodiment is an exemplification, and the method is not limited to the configuration in the embodiment.

<Outline of Manufacturing Process>

According to the manufacturing method, in the semiconductor device including a ferroelectric capacitor, a residual polarization quantity of the ferroelectric capacitor is predicted based on manufacturing parameters (physical quantities such as a material compositions, characteristics, dimensions, etc, a control quantity for prescribing a normal condition, a manufacturing target value, and so on) in a manufacturing process. Further, the residual polarization quantity is measured in the manufacturing process thereof. Then, the residual polarization quantity of the ferroelectric capacitor is controlled to a desired value by manipulating the manufacturing parameters in a process after the process of predicting or measuring the residual polarization quantity.

According to the method, for example, the residual polarization quantity is predicted from the manufacturing parameter in a first process and is adjusted by an adjusting step controlling a manufacturing parameter in a second process subsequent to the first process. Herein, the manufacturing parameter in the first process is exemplified by, e.g., physical quantities such as an orientation, a film thickness and a material composition, or film forming conditions such as a temperature when forming a film and a gas composition ratio in an atmosphere of a semiconductor substrate, thermal treatment conditions such as a temperature when annealing and a gas composition ratio in the atmosphere of the semiconductor substrate when annealing, and, for others, a control quantity when manufactured.

Further, the manufacturing parameter in the subsequent second process is exemplified by control quantities such as an area of the upper electrode, thermal treatment conditions when forming a shape (pattern) of the upper electrode or after forming the shape of the upper electrode, an area of the lower electrode, an orientation of the lower electrode, an orientation of the ferroelectric substance (material), thermal treatment conditions after forming the shape of the lower electrode, thermal treatment conditions after forming the lower electrode, conditions for forming the film of the lower electrode, conditions for forming the film of the ferroelectric substance, conditions for forming the film of the upper electrode, and conditions for forming a protection film.

The adjusting step may include forming, if a predicted value of a residual polarization quantity of the ferroelectric capacitor portion based on the manufacturing parameters of the ferroelectric capacitor portion is smaller than a target value, the area of the upper larger than a normal value.

Moreover, the adjusting step may include forming, if the predicted value of the residual polarization quantity of the ferroelectric capacitor portion based on the manufacturing parameters of the ferroelectric capacitor portion is larger than the target value, the area of the upper smaller than the normal value. Thus, according to the method, the area of the upper electrode is adjusted corresponding to the predicted value of the residual polarization quantity of the ferroelectric capacitor portion, and the residual polarization quantity can be adjusted to the target value.

Further, according to the present invention, after forming the shape of the upper electrode, the area of the lower electrode may also be adjusted corresponding to a measured value of the residual polarization quantity. Thus, according to the present invention, the area of the lower electrode is adjusted corresponding to the measured value of the residual polarization quantity of the ferroelectric capacitor portion, and the residual polarization quantity can be adjusted to the target value.

Still further, according to the present invention, the thermal treatment conditions after forming the upper electrode and other control quantities may also be adjusted corresponding to at least one of the predicted value and the measured value of the residual polarization quantity. Thus, according to the method, the manufacturing parameters are adjusted corresponding to the measured value of the residual polarization quantity of the ferroelectric capacitor portion, and the residual polarization quantity can be adjusted to the target value.

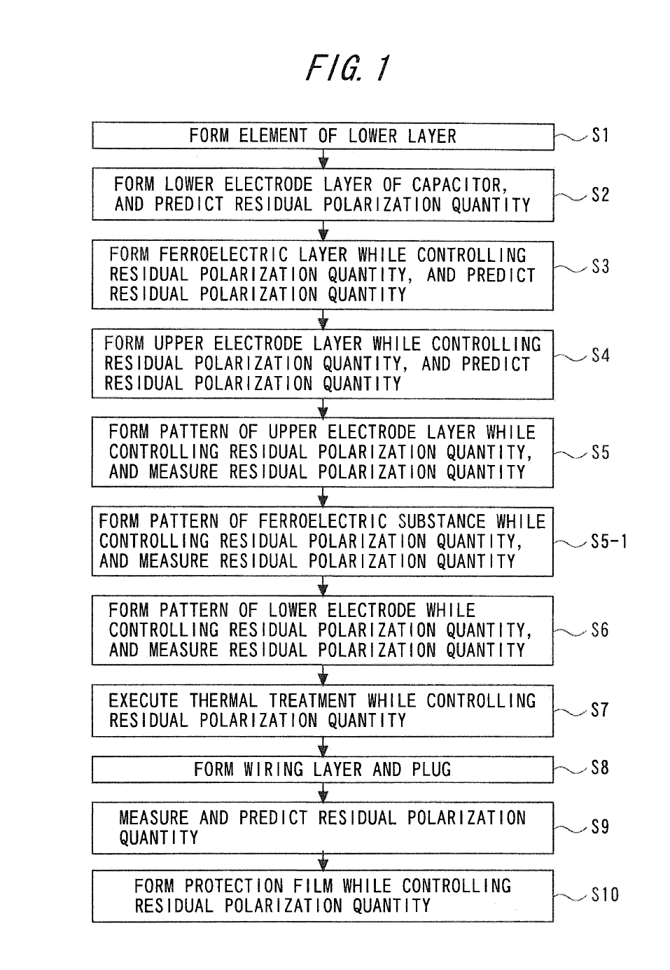

FIG. 1 shows an outline of the process of manufacturing the semiconductor device. FIG. 1 shows an outline of the process of manufacturing a ferroelectric memory. A characteristic of the manufacturing process lies in predicting or actually measuring the residual polarization quantity of the capacitor, which is included in the ferroelectric memory, from the physical quantities in the present process, and in adjusting the manufacturing parameters in the next process on the basis of the predicted value or the measured value. Thus, if the residual polarization quantity predicted in the present process deviates from a range of the target value, the manufacturing parameters are changed in the next process so that the residual polarization quantity gets approximates to the target value, and the residual polarization quantity is controlled.

In this process, to begin with, an element of a lower layer under the capacitor is formed on a semiconductor substrate (which is also called a wafer) (S1). The element of the lower layer is, e.g., a transistor.

Further, after an inter-layer film etc has been formed, a lower electrode layer of the capacitor is formed (S2). In this state, a lower electrode material is deposited to form a film over the entire surface of the semiconductor substrate. At this time, a physical quantity of the lower electrode, e.g., crystalline orientation (simply called as orientation in the embodiment) of the lower electrode, is measured, and the residual polarization quantity of the capacitor is predicted based on this physical quantity.

A relationship between the physical quantity and the residual polarization quantity may be empirically measured beforehand. For example, in the case of predicting the residual polarization quantity from the orientation of the lower electrode, it may suffice as follows. Namely, supposing that the physical quantities, other than the crystalline orientation, of the lower electrode are within the range of the target values, it may suffice that the value acquired as the final residual polarization quantity in a case that the crystalline orientation of the lower electrode takes a value is empirically obtained. Moreover, another available scheme is that a plurality of physical quantities, other than the crystalline orientation, of the lower electrode is set as conditions (the values thereof are designated as the parameters), and a relationship between the crystalline orientation of the lower electrode and the final residual polarization quantity is empirically obtained. Note that the “orientation” connotes herein a direction of a crystalline plane indicated by a so-called Miller index. (For example, QSW (a switching charge value) decreases as the parameter of another parameter of the lower electrode if the lower electrode is formed thinner than a predetermined film thickness, however, the value of the crystalline orientation of the lower electrode changes when the lower electrode is formed thinner than the predetermined film thickness. While on the other hand, the QSW does not change so much if the lower electrode is formed thicker than the predetermined film thickness. Further, in this case, the value of the crystalline orientation of the lower electrode remains almost unchanged).

Next, a ferroelectric layer is formed based on the predicted value obtained in S2 while controlling the residual polarization quantity in a way that adjusts the manufacturing parameters (S3). Herein, the manufacturing parameters are exemplified by thermal treatment conditions for crystallizing the ferroelectric layer, such as an annealing temperature, a period of annealing time and a gas composition ratio in an atmosphere to which the semiconductor substrate is exposed when conducting an annealing process. Further, the manufacturing parameters can involve using a film thickness of the ferroelectric substance, a composition of a material of which the ferroelectric substance is composed, etc. The film thickness of the ferroelectric substance can be measured and may also use a target value when manufactured. Moreover, the composition of the material of which the ferroelectric substance is composed, when PZT (lead zirconate titanate) is used as the ferroelectric substance, represents a percentage content (i.e., a ratio given by Pb/(Zr+Ti)). This composition may be measured by a known technique such a spectrometric analysis, and may involve using a target value when manufactured.

In this state, the lower electrode material is deposited to form the film over the entire surface of the semiconductor substrate and then crystallized. After crystallizing the ferroelectric layer, the physical quantities of the ferroelectric substance are measured, and the residual polarization quantity of the capacitor is predicted based on these physical quantities. The physical quantities connote herein, e.g., the crystalline orientation, the film thickness, the material composition, etc of the ferroelectric layer. The orientation can be obtained by X-ray diffraction. The film thickness may be measured by, e.g., an optical interference method. Moreover, the manufacturing target value may be employed as the film thickness. A percentage content of the lead may be measured by the known technique such as the spectrometric analysis and may involve employing the target value when manufactured.

Next, an upper electrode layer is formed based on the predicted value in S3 while controlling the residual polarization quantity by adjusting the manufacturing parameters (S4). The manufacturing parameters are herein exemplified by a light reflectance (simply called as reflectance or reflectivity in the embodiment) of the upper electrode, a film thickness of the upper electrode, an oxidation quantity, a gas ratio in the atmosphere to which the semiconductor substrate is exposed when forming the film, a period of sputtering time in the case of forming the film by sputtering, and input electric power (power) to a sputtering apparatus. Moreover, the residual polarization quantity may also be controlled by adjusting the thermal treatment conditions after the film formation. Then, the residual polarization quantity is predicted by measuring the variety of physical quantities at the present.

Herein, the variety of physical quantities are, for example, a reflectance, a specific resistance, etc of the upper electrode. Further, when the upper electrode is composed of a 2-layered film, the residual polarization quantity can be also predicted by use of a ratio of the physical quantities between the two films (layers), i.e., a ratio of the reflectance or a ratio of the specific resistance.

Next, a pattern of the upper electrode is formed based on the measured value or the predicted value in S4 while controlling the residual polarization quantity by adjusting the manufacturing parameter (S5). The manufacturing parameter is herein exemplified by an area of the upper electrode. The area of the upper electrode can be controlled by an area of a resist for patterning the upper electrode, i.e., an area of the pattern on a reticle, which is transferred onto the resist. To describe it more specifically, the area of the upper electrode is controlled by the pattern area on the reticle, however, a plurality of reticles must be prepared in order for the area on the reticle to change, and hence this is not efficient. Normally, the same reticle is employed, and it is preferable that the formation be done in a way that controls the pattern area of the resist by making an exposure quantity variable.

Moreover, the area of the upper electrode can be controlled based on etching conditions such as a period of etching time when etching with the resist serving as a mask and a composition ratio of an etching gas. A selection ratio of the resist and the upper electrode material can be controlled by the composition ratio of the etching gas, and therefore the final upper electrode area can be adjusted. For example, if the selection ratio of the etching decreases while increasing a taper angle defined as an inclination of the side face of the upper electrode to a direction of a plane-normal line of the semiconductor substrate, the upper portion shrinks with the result that the area of the upper electrode decreases. Further, if the selection ratio of the etching increases while decreasing the taper angle defined as the inclination of the side face of the upper electrode to the direction of the plane-normal line of the semiconductor substrate, the area of the upper electrode increases. This is because the side face of the upper electrode gets vertical to the direction of the plane-normal line of the semiconductor substrate, and the upper portion does not shrink.

Furthermore, the residual polarization quantity may also be controlled by adjusting thermal treatment conditions (these thermal conditions are called recovery anneal. Normally, the recovery anneal requires a considerable temperature (high temperature) and a gas containing oxygen.) in a thermal treatment after the etching. Further, in the process in 5, after patterning the upper electrode, the residual polarization quantity is measured.

The residual polarization quantity can be measured in such a way that one of a pair of probes comes into contact with the pattern of the upper electrode and the other probe comes into contact with the ferroelectric substance. For example, a Sawyer-Tower circuit may be applied to a measuring circuit. Next, the pattern of the ferroelectric substance is formed based on the measured value or the predicted value in S5 while controlling the residual polarization quantity by adjusting the manufacturing parameter (S5-1).

Herein, the manufacturing parameter is, e.g., an area of the ferroelectric substance. The area of the ferroelectric substance can be controlled by an area of a resist for patterning the ferroelectric substance, i.e., an area of the pattern on a reticle, which is transferred onto the resist. Further, the area of the ferroelectric substance can be controlled by the etching conditions such as a period of etching time when etching with the resist serving as a mask and a composition ratio of an etching gas.

Moreover, the residual polarization quantity may also be controlled by adjusting the thermal treatment conditions (these thermal conditions are called the recovery anneal. Normally, the recovery anneal requires the considerable temperature (high temperature) and the gas containing oxygen.) in the thermal treatment after the etching. Further, in the process in S5-1, after patterning the ferroelectric substance, the residual polarization quantity is measured.

Next, the pattern of the lower electrode is formed based on the measured value in S5 while controlling the residual polarization quantity by adjusting the manufacturing parameter (S6). Herein, the manufacturing parameter is, e.g., an area of the lower electrode. The area of the lower electrode can be controlled by an area of the resist for patterning the lower electrode, i.e., an area of the pattern on the reticle, which is transferred onto the resist.

Moreover, the area of the lower electrode can be controlled by the etching conditions such as a period of etching time when etching with the resist serving as a mask and a composition ratio of an etching gas. A selection ratio of the resist and the lower electrode material can be controlled by the composition ratio of the etching gas, and hence the final lower electrode area can be adjusted. Further, in the process in S6, after patterning the lower electrode, the residual polarization quantity is measured.

Next, the thermal treatment is executed based on the measured value in S6 while controlling the residual polarization quantity by adjusting the manufacturing parameters (S7). The thermal treatment is a treatment for reducing damages caused in a variety of processes for forming the capacitor (generally, this thermal treatment is called the recovery anneal). Moreover, the manufacturing parameters are, e.g., a thermal treatment temperature and a period of thermal treatment time, or a composition of the gas in the atmosphere to which the semiconductor substrate is exposed during the thermal treatment.

Subsequently, a wiring layer and a plug layer above the capacitor are formed (S8). Further, the residual polarization quantity of the capacitor is measured (S9). This residual polarization quantity may be measured via a wiring pattern of the wiring layer.

Next, a protection film is formed based on the measured value in S9 while controlling the manufacturing parameter (S10). Herein, the manufacturing parameter is, e.g., a thermal treatment temperature or a period of thermal treatment time of the protection film. Herein, the residual polarization quantity of the capacitor formed under the protection film and the wiring layer is adjusted by adjusting a thermal treatment condition of the protection film formed on the uppermost layer of the semiconductor substrate.

<General Explanation of Control Procedures>

Each individual control procedure of the residual polarization quantity explained in the manufacturing process in FIG. 1 will be described.

(First Method)

A first method is realized by predicting the residual polarization quantity in the processes from S2 onward in FIG. 1 and by patterning the upper electrode in S5. To be specific, the predicted value of the residual polarization quantity is obtained from the manufacturing parameters of the semiconductor device up to the process of forming the upper electrode of the ferroelectric capacitor. If the predicted value is less than a target value, the ferroelectric capacitor is formed in a way that increases the area of the upper electrode of the ferroelectric capacitor above a value at the normal time or above a reference value. Whereas if the predicted value is more than the target value, the ferroelectric capacitor is formed in a way that reduces the area of the upper electrode of the ferroelectric capacitor. Herein, the value at the normal time or the reference value of the area of the upper electrode represents, e.g., a target value prescribed by design, a value determined from an actual result of the manufacturing process, and so on.

The prediction of the residual polarization quantity according to the embodiment involves using (1) the orientation of the lower electrode, (2) the crystalline orientation of the ferroelectric substance, (3) the film thickness of the ferroelectric crystal, (4) the crystallization annealing temperature when producing the ferroelectric crystal, (5) the a lead quantity in the PZT when the ferroelectric crystal is the PZT, (6) the light reflectance on the upper electrode and (7) the ratio of the physical quantities between the two layers when the upper electrode is composed of the 2-layered material.

(1) Prediction of Residual Polarization Quantity from Orientation of Lower Electrode

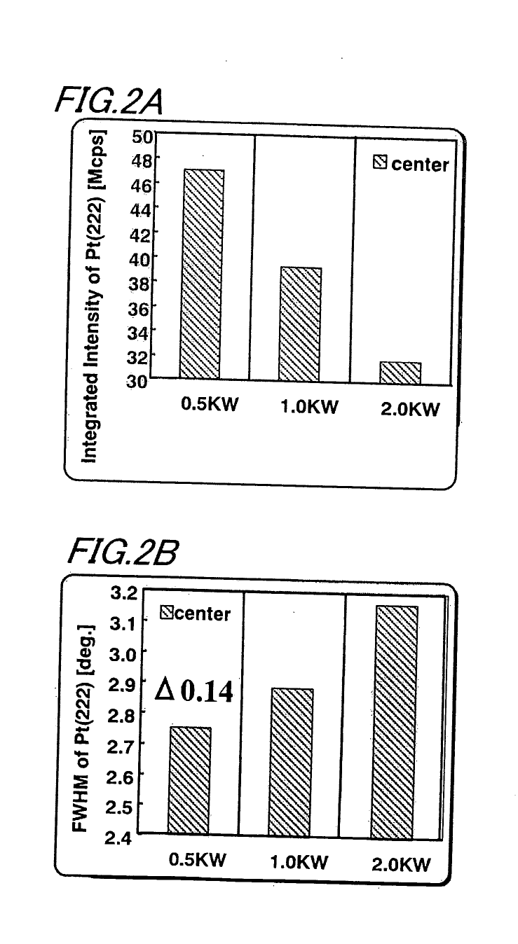

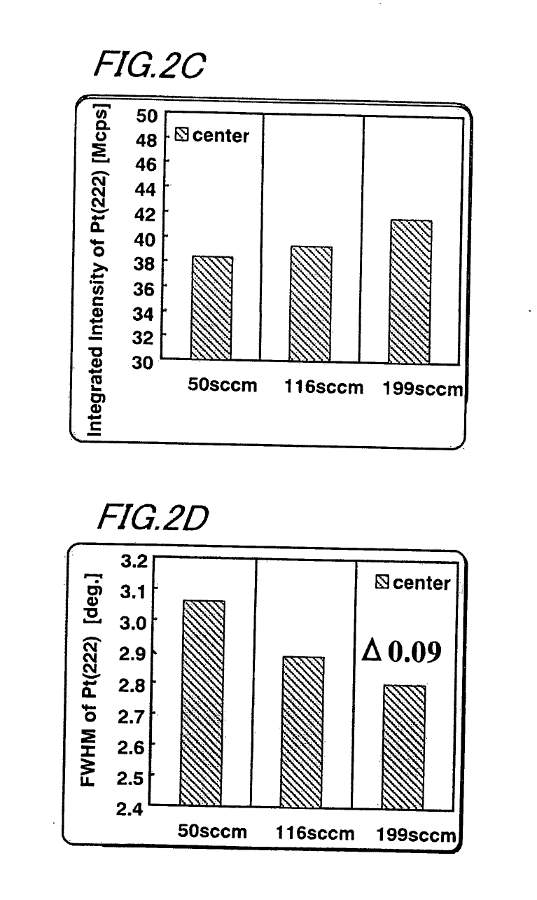

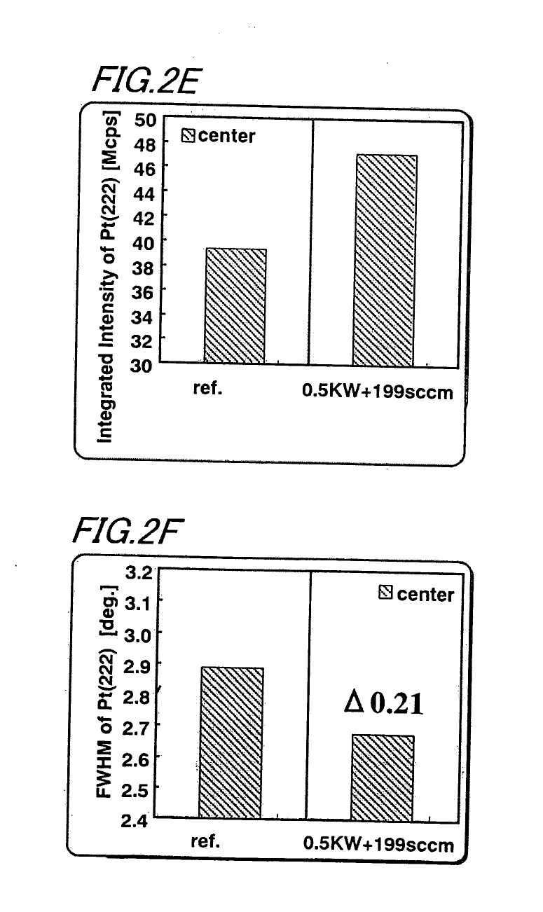

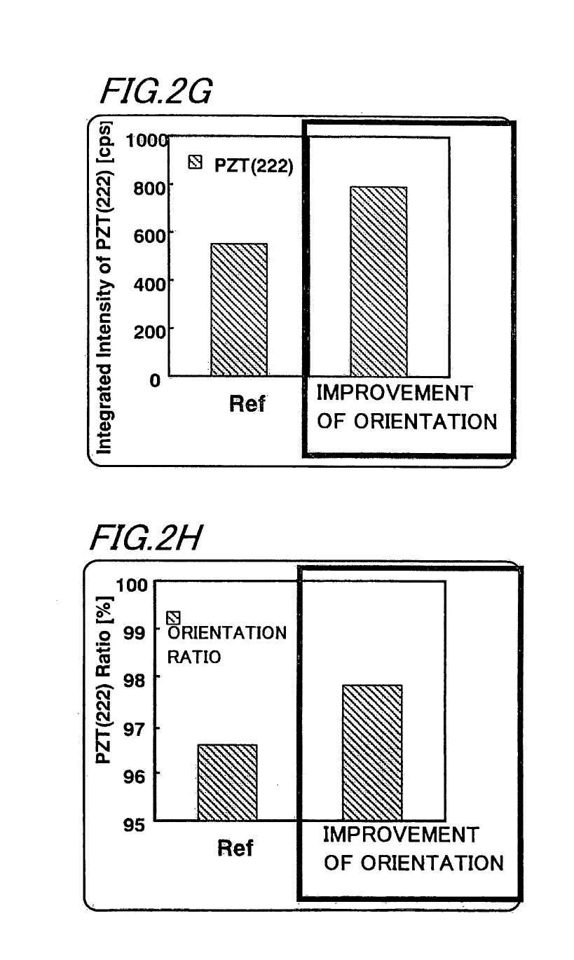

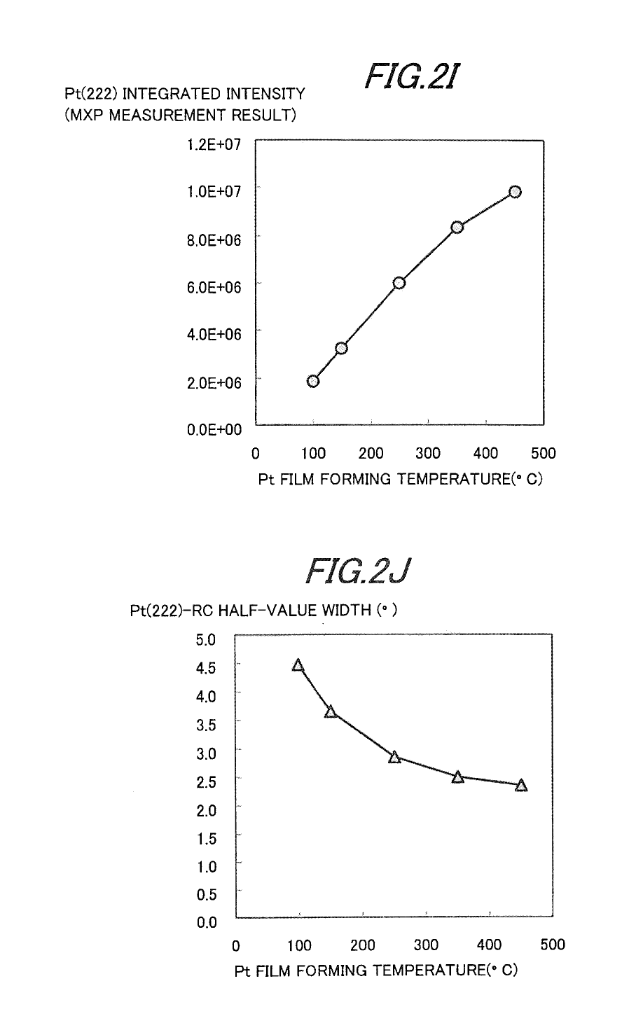

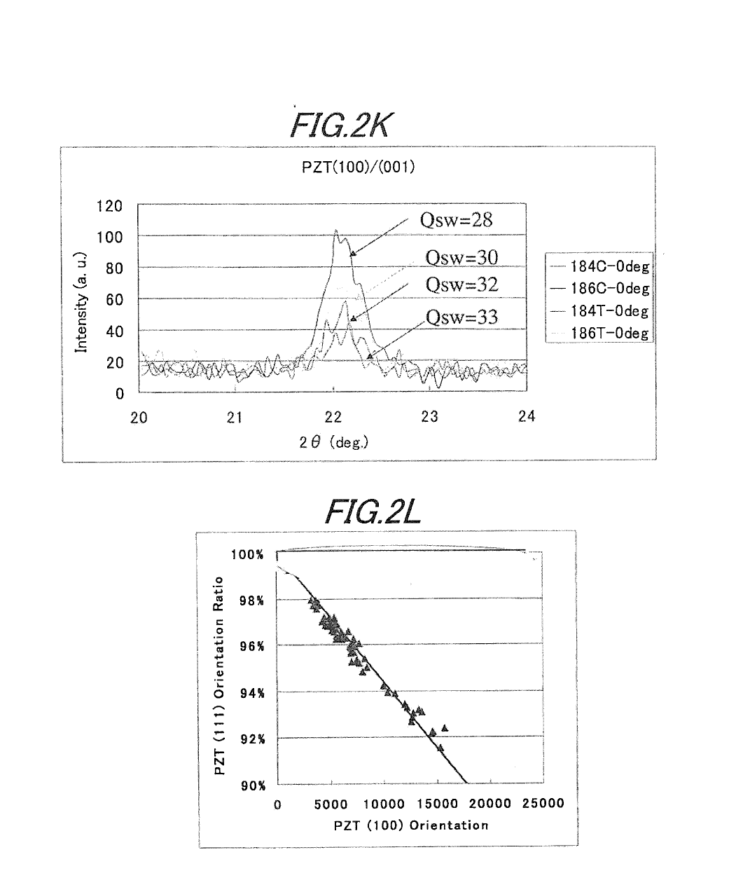

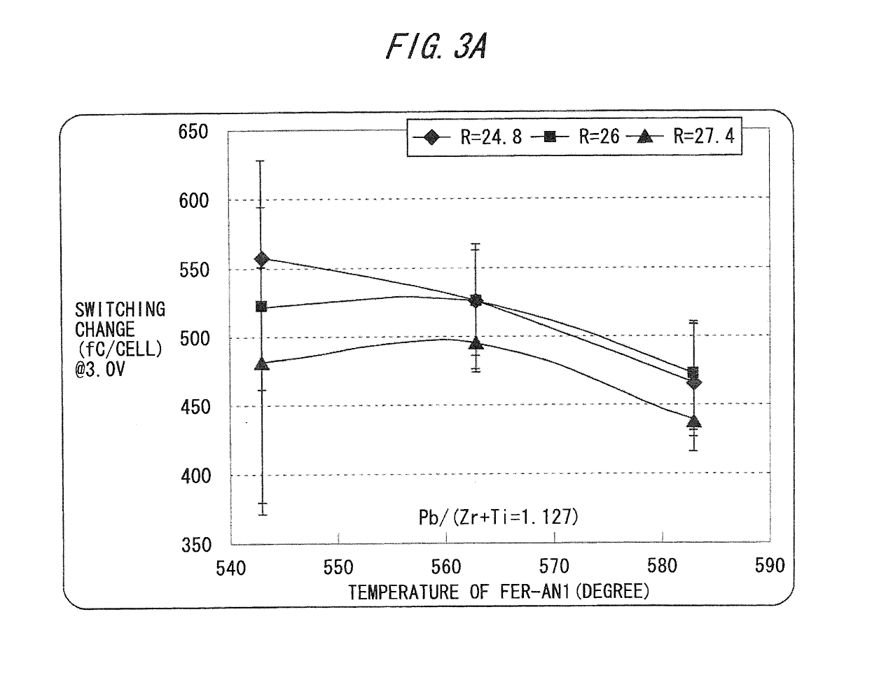

FIGS. 2A-2F show a relationship between a film forming condition and the orientation (<222> orientation) of the lower electrode. FIG. 2A shows input power to the sputtering apparatus when conducting the film formation by sputtering and the orientation of the formed lower electrode. FIG. 2B shows a half-value width of an intensity distribution (a rocking curve) of the X-ray diffraction in that case. Further, FIG. 2C shows an argon gas flow rate when conducting the film formation by sputtering and the orientation of the formed lower electrode. FIG. 2D shows a half-value width of an intensity distribution of the X-ray diffraction in that case.

FIG. 2E shows the orientation of the lower electrode in a case where the electric power and the argon gas flow rate when conducting the film formation by sputtering take reference values (indicated by “ref”), and the orientation of the lower electrode when under a condition of such a combination as to improve the orientation in FIGS. 2A and 2C, respectively. FIG. 2F shows a half-value width of an intensity distribution (the rocking curve) of the X-ray diffraction in that case. As illustrated in FIGS. 2A-2F, it is recognized that the orientation of the lower electrode can be controlled by changing the sputtering condition.

FIGS. 2I-2J show a relationship between a temperature when forming the film and the <222> orientation.

FIG. 2I shows the orientation based on an integrated intensity distribution of the light of X-ray diffraction, and FIG. 2J shows a half-value width of the intensity distribution. It is recognized from FIGS. 2I-2J that the orientation of the lower electrode can be controlled by the temperature when forming the film.

On the other hand, FIG. 2G shows, when controlling the <222> orientation of the lower electrode in the same procedures as those in FIGS. 2E-2F, the orientation of the ferroelectric substance (PZT) formed on the lower electrode thereof. Further, FIG. 2H shows an orientation ratio of the ferroelectric substance (PZT) at that time. The orientation represents a distribution of the detected intensity of the X-rays, and the orientation ratio is a ratio of the detected intensity, comparing other crystalline planes. When the <222> orientation of the lower electrode is improved, it is understood that the <222> orientation of the ferroelectric substance above the lower electrode is improved.

Then, if the relationship between the orientation of the ferroelectric substance and the residual polarization quantity is empirically measured, the residual polarization quantity of the ferroelectric substance can be predicted by measuring the orientation of the lower electrode. Namely, the PZT orientation is estimated from the orientation of the lower electrode, and the residual polarization quantity may be predicted from the PZT orientation.

(2) Prediction of Residual Polarization Quantity from Orientation of Ferroelectric Crystal

FIG. 2K shows a relationship between the orientation of the ferroelectric substance (PZT) and the residual polarization quantity of the ferroelectric capacitor using PZT as the dielectric substance. As in FIG. 2K, when the PZT orientation gets dominated at <100>, the residual polarization quantity decreases.

FIG. 2L shows a relationship between a <100> orientation and a <111> orientation in the same sample of the ferroelectric substance (PZT). As shown in FIG. 2L, a PZT<100> intensity and a PZT<111> intensity have a correlation with each other, in which as a PZT<100> orientation ratio rises, a PZT<111> orientation ratio lowers. Note that <111> and <222> represent physically the same diffracting direction.

Accordingly, the residual polarization quantity can be predicted by empirically measuring the relationship between the orientation and the residual polarization quantity as shown in FIG. 2K. Namely, in the manufacturing process of the semiconductor device including the ferroelectric capacitor, after forming the ferroelectric crystal, the residual polarization quantity can be predicted indirectly by measuring the orientation of the crystal.

(3) Prediction of Residual Polarization Quantity from Ferroelectric Crystal

Generally, it is known in an FeRAM (Ferroelectric Random Access Memory) that the residual polarization quantity increases when having a large ferroelectric crystal film thickness between the electrodes building up the capacitor. Such being the case, in an FeRAM manufacturing process, after forming the ferroelectric crystal, the residual polarization quantity can be predicted by measuring a film thickness of the ferroelectric crystal.

(4) Prediction of Residual Polarization Quantity from Crystallization Annealing Temperature When Producing Ferroelectric Crystal

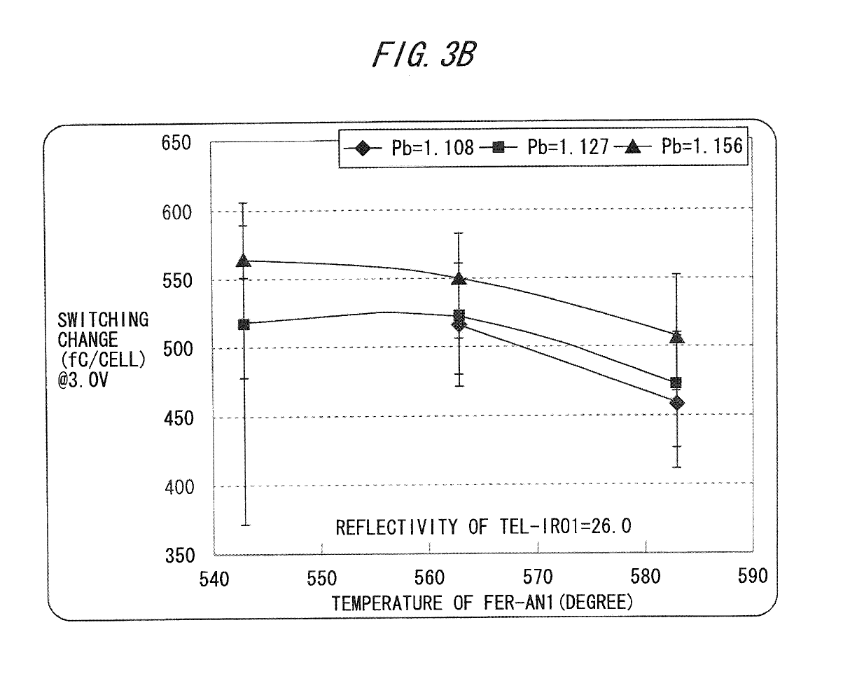

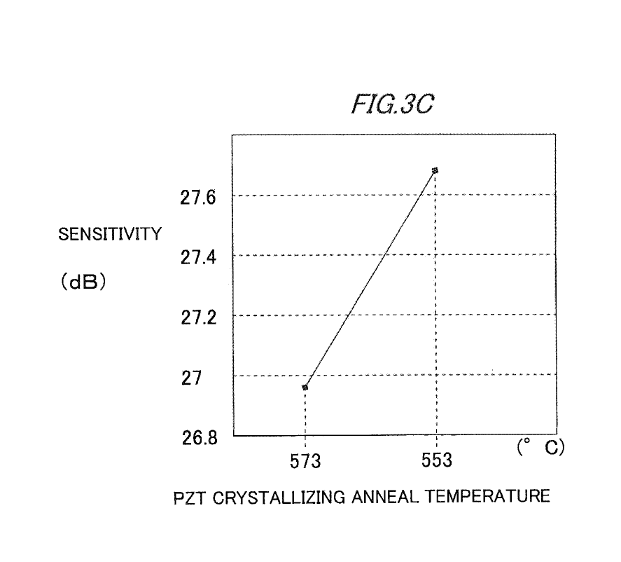

FIGS. 3A and 3B show a relationship between a crystallization annealing temperature when producing the PZT crystal and the residual polarization quantity of the FeRAM containing the PZT generated by the crystallization anneal. FIG. 3A shows a result when a relative lead quantity is 1.127 and when defining a relative lead quantity (Pb) in the PZT by Pb quantity/(Zr quantity+Ti quantity). Further, respective graphs in FIG. 3A represent measurement quantities in the case of changing a light reflectance (reflectivity) R, as a parameter, of the upper electrode serving as a component of the FeRAM.

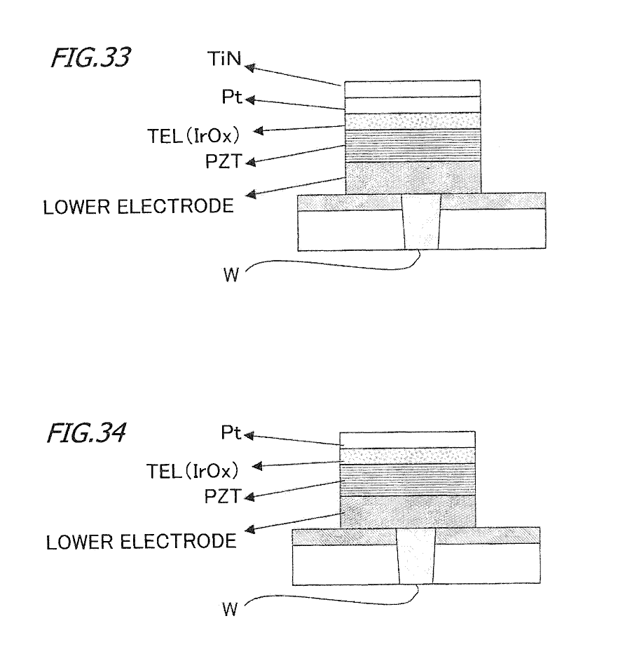

Moreover, FIG. 33 shows results when the light reflectance R of the upper electrode is 26 percent (R=26) (a measurement wavelength is on the order of 480 nm). Graphs in FIG. 3B respectively show measurement quantities in the case of changing, as a parameter, a relative lead quantity of the PZT of which the FeRAM is composed.

Moreover, FIG. 3C shows sensitivities according to quality engineering as degrees of influence of the PZT crystallization annealing temperature upon the residual polarization quantity. This graph shows the PZT crystallization annealing temperatures as values varied from 573° C. down to 553° C., however, it is comprehended that the residual polarization quantity gets large when the crystallization annealing temperature is lowered down to 553° C. in this range. The degree of influence of the crystallization anneal differs depending on the composition (manufacturing method) of the ferroelectric capacitor, and therefore this is no more than the result of one example.

Further, the changes of the sensitivity (dB) is as low as being less than “1” due to the change in the PZT crystallization annealing temperature, however, this is also no more than the result of one example because of the value being increased and decreased depending on the composition (manufacturing method) of the ferroelectric capacitor. As in FIG. 3C, concerning the ferroelectric substance used this time, when the crystallization annealing temperature is within the range of 553 degrees through 573 degrees, the result obtained is that the residual polarization quantity becomes larger as the temperature gets lower.

As shown in FIGS. 3A through 3C, in a state where the conditions such as the reflectance (reflectivity) of the upper electrode and the relative lead quantity of the PZT are set to predetermined values, and the crystallization annealing temperature is obtained, thereby enabling the residual polarization quantity to be predicted.

(5) Prediction of Residual Polarization Quantity from Lead Quantity in PZT

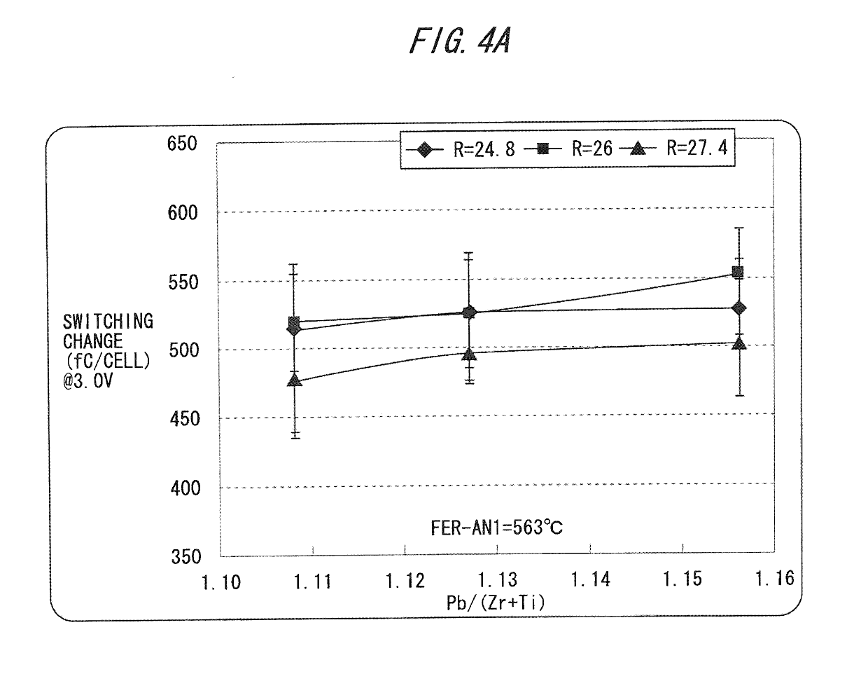

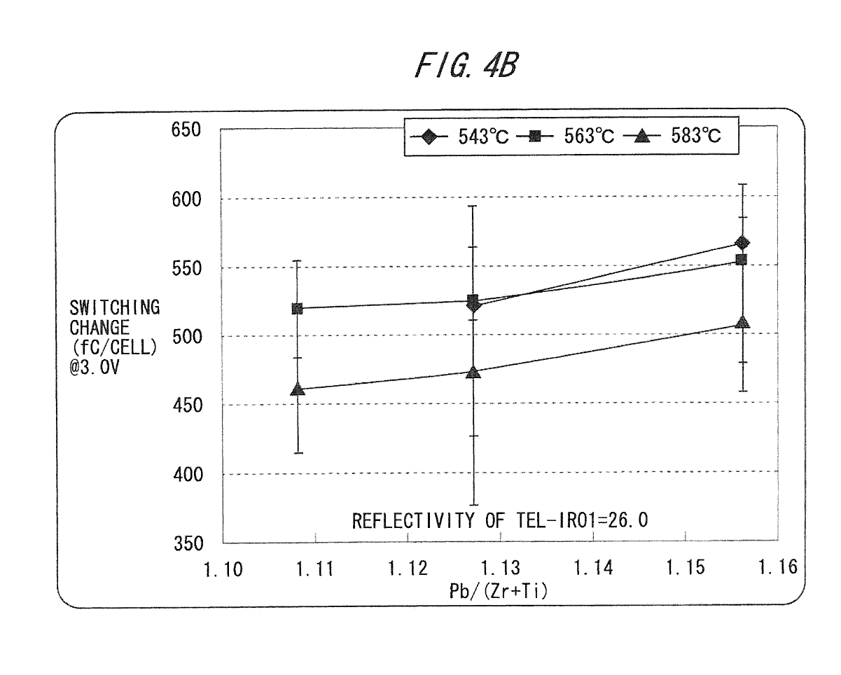

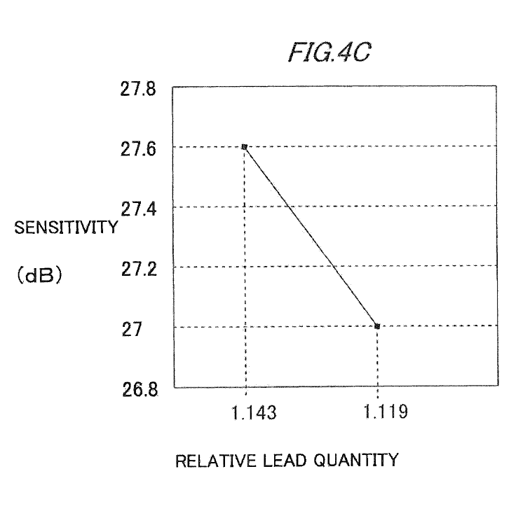

FIGS. 4A and 4B show a relationship between the relative lead quantity in the PZT crystal and the residual polarization quantity of the FeRAM containing the PZT. Herein, as described in the item (4), the relative lead quantity in the PZT is defined by Pb quantity/(Zr quantity+Ti quantity).

FIG. 4A shows a result when the relative lead quantity is changed in a range of 1.1 through 1.16 in a state where the PZT crystallization annealing temperature is fixed to Celsius 563 degrees. Further, graphs in FIG. 4A respectively show measurement quantities in the case of changing, as a parameter, the light reflectance R of the upper electrode of which the FeRAM is constructed.

Moreover, FIG. 4B shows results when the light reflectance R of the upper electrode is 26 percent (R=26). Graphs in FIG. 4B respectively show measurement quantities in the case of changing, as a parameter, the PZT crystallization annealing temperature.

Further, FIG. 4C shows the sensitivities according to the quality engineering as degrees of influence of the relative lead quantity in the PZT upon the residual polarization quantity. As in FIG. 4C, in the composition of the ferroelectric substance employed this time, when the Pb quantity is between 1.119 and 1.143, a result obtained is that the residual polarization quantity gets large as the relative lead quantity in the PZT becomes large.

As shown in FIGS. 4A through 4C, if the conditions such as the reflectance of the upper electrode and the crystallization annealing temperature are set to the predetermined values, the residual polarization quantity can be predicted by obtaining the relative lead quantity of the PZT.

(6) Prediction of Residual Polarization Quantity from Light Reflectance on Upper Electrode

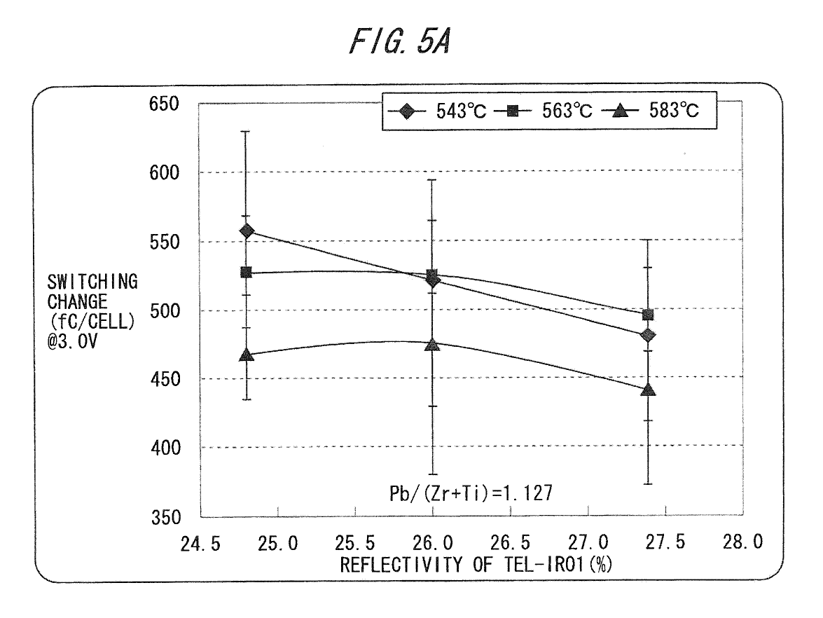

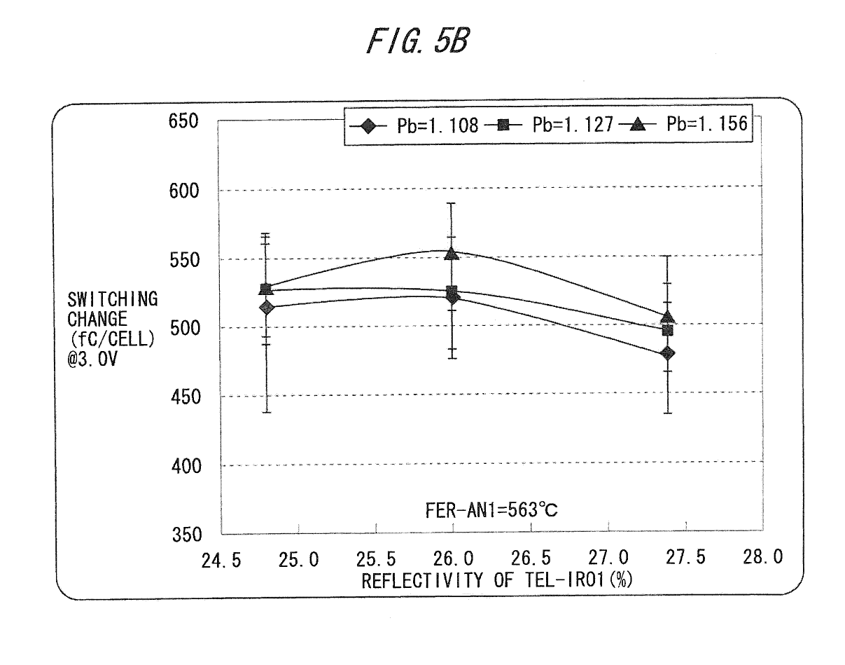

FIGS. 5A and 5B show a relationship between the light reflectance of the upper electrode and the residual polarization quantity of the FeRAM including the upper electrode. An assumption herein is that the FeRAM has the capacitor including the upper electrode, the ferroelectric layer of the PZT and the lower electrode.

FIG. 5A shows measurement results obtained when the relative lead quantity is fixed to 1.127 in the case of defining the relative lead quantity in the PZT by Pb quantity/(Zr quantity+Ti quantity) and when the reflectance of the upper electrode is changed in a range of 24.5 percent through 28 percent. Further, respective graphs in FIG. 5A show measurement quantities in the case of changing the PZT crystallization annealing temperature as a parameter.

Moreover, FIG. 5B shows measurement results in a state where the PZT crystallization annealing temperature is fixed to Celsius 563 degrees. Further, respective graphs in FIG. 5B show measurement quantities in the case of changing, as a parameter, of a relative lead length of the PZT of which the FeRAM is composed.

As shown in FIGS. 5A and 5B, in a state where the conditions such as the relative lead quantity of the PZT and the PZT crystallization annealing temperature are set to the predetermined values, the residual polarization quantity can be predicted by obtaining the reflectance of the upper electrode.

(7) Prediction of Residual Polarization Quantity from Ratio of Physical Characteristic Quantity between Two Layers When Upper Electrode is Composed of 2-Layered Material

If the upper electrode of the capacitor included in the FeRAM is composed of a plurality of 2-layered materials, there may be previously acquired a relationship between a ratio of the physical characteristics between the two layers and the residual polarization quantity. These physical characteristics can be exemplified such as a light reflectance and a specific resistance of each of the two layers. Then, on the occasion of actually manufacturing the FeRAM, the residual polarization quantity can be predicted by measuring a ratio of the physical characteristic quantity between the layers.

### (8) Control of Residual Polarization Quantity

If the residual polarization quantity could be predicted by any one of the methods (1)-(7), a control method of making approximation to the target value by increasing and decreasing the residual polarization quantity can be exemplified by increasing or decreasing the upper electrode area. Namely, based on the prediction result, if the residual polarization quantity is larger than a design value, it may suffice that the area of the upper electrode is reduced. Further, based on the prediction result, if the residual polarization quantity is smaller than the design value, it may suffice that the area of the upper electrode is enlarged.

The area of the upper electrode may be controlled by increasing and decreasing, e.g., the area of the resist pattern for patterning the upper electrode. For example, the increase or the decrease of the resist pattern may be done by increasing or decreasing, e.g., dimensions of the reticle pattern. Further, even in the case of using the same reticle, the dimensions of the resist pattern may be increased or decreased by increasing or decreasing an exposure quantity. Moreover, the dimensions of the post-etching upper electrode may be increased or decreased by changing an etching quantity or a selection ratio of the etching with respect to the resist pattern in the same position.

(Second Method)

A second method is realized by measuring the residual polarization quantity in the process in S5 in FIG. 1 and by patterning the lower electrode in S6. Specifically, after forming the upper electrode of the ferroelectric capacitor, the residual polarization quantity of the ferroelectric capacitor is actually measured before patterning the lower electrode. The measuring method involves measuring the residual polarization quantity by use of the hitherto-known Sawyer-Tower circuit in a way that makes the probes come into contact with the upper electrode and the ferroelectric substance, respectively.

Then, if the measured value is under the target value, the ferroelectric capacitor is formed by increasing the area of the lower electrode of the ferroelectric capacitor over the value at the normal time or the reference value. On the other hand, if the predicted value is over the target value, the ferroelectric capacitor is formed by decreasing the area of the lower electrode of the ferroelectric capacitor under the value at the normal time or the reference value.

A method of controlling the area of the lower electrode is the same as by controlling the area of the upper electrode. Namely, the dimensions of the post-etching lower electrode may be increased or decreased by changing the area of the resist pattern, the etching quantity or the selection ratio of the etching.

(Third Method)

A third method is realized by measuring the residual polarization quantity in the process in S6 in FIG. 1 and by the thermal treatment in S7. Namely, after patterning the lower electrode, the residual polarization quantity is measured. The measuring method is the same as in the case of the second method.

Then, if the measured value is under the target value, the residual polarization is accelerated by the recovery anneal. The recovery anneal represents a process of reducing the damages the capacitor material suffered from etching or sputtering after the ferroelectric capacitor has been formed.

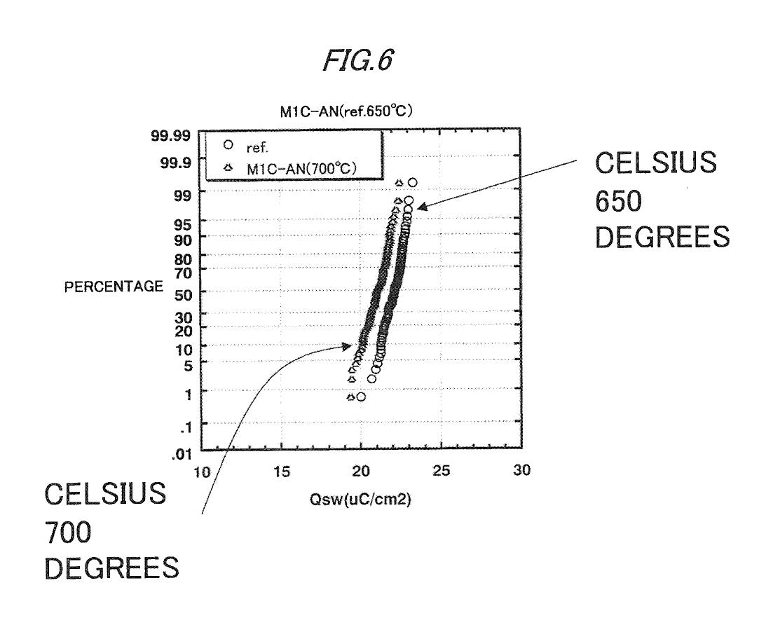

FIG. 6 shows the residual polarization quantity in the case of implementing the recovery anneal at the reference value (Celsius 650 degrees) and the residual polarization quantity in the case of implementing the recovery anneal at a temperature (Celsius 700 degrees) higher by 50 degrees than the reference value. Thus, the residual polarization quantity of the ferroelectric capacitor can be controlled depending on the temperature condition when performing the recovery anneal. Accordingly, a relationship between the temperature condition and the residual polarization quantity is obtained beforehand for every type of element, and it may suffice that a desired annealing temperature is set from the residual polarization quantity measured before the recovery anneal.

Further, the annealing time may also be controlled in place of controlling the annealing temperature when performing the recovery anneal. In this case also, a relationship between the annealing time and an amount of variation in the residual polarization quantity is empirically measured beforehand, and it may suffice that a necessary increment and decrement of the annealing time are determined.

(Fourth Method)

A fourth method is realized by predicting the residual polarization quantity in the process in S9 in FIG. 1 and by the thermal treatment when forming the protection film in S10. To be specific, after forming the uppermost wiring layer, the residual polarization quantity is measured. In this case, the probe comes into contact with a pad pattern, and the residual polarization quantity is measured via the wiring layer.

Then, if the measured value is under the target value, the residual polarization is accelerated in the process of the thermal treatment of polyimide. On the other hand, if the measured value is over the target value, the residual polarization is restrained in the process of the thermal treatment of the polyimide. The polyimide is a resinous material for covering the uppermost layer of the semiconductor device. The polyimide is hardened by the thermal treatment.

Generally, when a temperature of the thermal treatment of the polyimide is raised and if a hydrogen barrier layer or a moisture barrier layer does not exist under the polyimide layer, the hydrogen or moisture contained in the upper layer of the capacitor is easy to permeate the PZT. When the hydrogen or the moisture permeates the PZT, the PZT is reduced by the hydrogen and deteriorated. As a result, the residual polarization quantity gets smaller as the temperature of the thermal treatment of the polyimide set higher.

Accordingly, in the semiconductor device including neither the hydrogen barrier layer nor the moisture barrier layer, in the case of decreasing the residual polarization, it may suffice that the temperature of the thermal treatment of the polyimide is raised. Furthermore, in the case of accelerating the residual polarization, it may suffice that the temperature of the thermal treatment of the polyimide is lowered. Normally, however, at least a single layer of protection film (the hydrogen barrier layer) is provided between the PZT dielectric film and the polyimide layer. Moreover, it is required that the protection film (the hydrogen barrier film) be provided along the periphery of the PZT ferroelectric capacitor.

Further, if the hydrogen barrier layer or the moisture barrier layer exists under the polyimide layer, there is less of influence of the hydrogen or the moisture contained in the upper layer of the capacitor. In this case, when the temperature of the thermal treatment of the polyimide is set higher than normal, the residual polarization quantity increases. While on the other hand, when the temperature of the thermal treatment of the polyimide is set lower than normal, the residual polarization quantity decreases. Normally, however, at least the single layer of protection film (the hydrogen barrier layer) is provided between the PZT dielectric film and the polyimide layer. Further, it is required that the protection film (the hydrogen barrier film) be provided along the periphery of the PZT ferroelectric capacitor.

In any case, the relationship between the temperature of the thermal treatment of the polyimide and the residual polarization quantity is empirically collected beforehand, and it may be determined based on the measurement result of the residual polarization quantity which method, how much the temperature of the thermal treatment of the polyimide is increased or decreased, or this temperature is set as normal.

(Fifth Method)

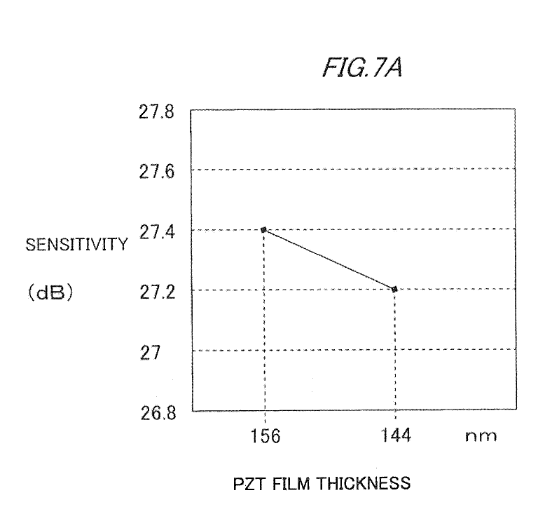

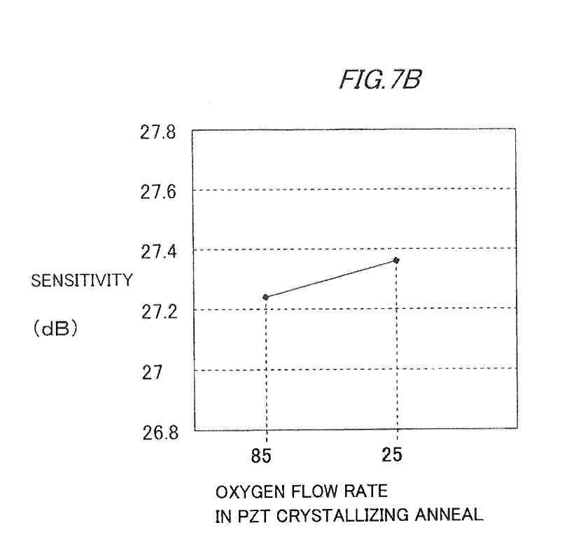

A fifth method is applied to a case in which the ferroelectric crystal is composed of PZT and can be realized as the process in S3 in FIG. 1. Namely, the residual polarization quantity is predicted from the lead quantity in the PZT and from the film thickness of the PZT crystal. FIG. 7A shows a relationship between the film thickness of the PZT and the residual polarization quantity. FIG. 7A shows the sensitivities according to the quality engineering with respect to the film thickness of the PZT by way of the residual polarization quantities. Generally, the residual polarization quantity becomes larger as the PZT film gets thicker. (Herein, the result shows a slight difference in the sensitivity (dB), however, this differs depending on the composition (manufacturing method) of the ferroelectric substance, and hence the sensitivity is no more than one example.)

If the predicted value of the residual polarization quantity is under the target value, the residual polarization is accelerated in the crystallizing process of the PZT.

Moreover, the residual polarization quantity can be also controlled by an oxygen flow rate when performing the crystallizing anneal. FIG. 7B shows a relationship between the oxygen flow rate when performing the crystallizing anneal and the residual polarization quantity. Specifically, if the predicted value of the residual polarization quantity is under the target value, it may suffice that the oxygen flow rate is set smaller than normal. (Herein, the result shows a slight difference in the sensitivity (dB), however, this differs depending on the composition (manufacturing method) of the ferroelectric substance, and therefore the sensitivity is no more than one example.)

Whereas if the predicted value is over the target value, the residual polarization is restrained in the crystallizing process of the PZT. For example, it may also suffice that the oxygen flow rate is increased when conducting the crystallizing anneal.

It may also suffice that a relationship between an amount of variation in each of these crystallizing conditions (the annealing temperature, the annealing time and the oxygen flow rate) and an amount of variation in the residual polarization quantity is empirically measured beforehand. Then, the crystallizing condition may be determined from the predicted value of the residual polarization quantity.

(Sixth Method) (Corresponding to Notes 19-20)

A sixth method is applied to the post-crystallizing process of the ferroelectric substance, i.e., applied to the process in S4 in FIG. 1. The residual polarization quantity may also be controlled by controlling the light reflectance of the upper electrode on the basis of, if a necessary case may arise, the predicted value of the residual polarization quantity after crystallizing the ferroelectric substance. The predicted value of the residual polarization quantity after the crystallization may be obtained in the same way as by the second method.

Herein, the “necessary case” is determined from a result of predicting the residual polarization quantity from the lead quantity in the PZT and from the film thickness of the PZT crystal by the fifth method and determined from a result of carrying out the control of accelerating or restraining the residual polarization in the PZT crystallizing process by the fifth method. Based on these results, further if there is a necessary case for controlling the residual polarization quantity, the sixth method is executed. The result of predicting the residual polarization quantity and the result of conducting the control of accelerating or restraining the residual polarization in the PZT crystallizing process may be accumulated as, e.g., empirical values or actual result values.

Then, if an effect in controlling the residual polarization quantity by performing the control of accelerating or restraining the residual polarization in the PZT crystallizing process is insufficient, the residual polarization quantity is controlled by controlling the reflectance of the upper electrode. In this case, as illustrated in FIGS. 5A and 5B, the residual polarization quantity can be controlled by controlling the reflectance of the upper electrode.

(Seventh Method)

A seventh method is carried out in the annealing process executed next in addition to the control of the reflectance, which is defined as the sixth method. Namely, the residual polarization quantity can be also controlled by the annealing process after forming the upper electrode.

In this case also, it may suffice that a relationship between the annealing time and the annealing temperature when in the annealing process, or the oxygen flow rate and the residual polarization quantity is previously measured. For example, it may suffice that a relationship between the amount of variation from the normal value and the residual polarization quantity is obtained. Then, the annealing time, the annealing temperature or the oxygen flow rate may be determined from the predicted value of the residual polarization quantity after forming the upper electrode.

(Eighth Method)

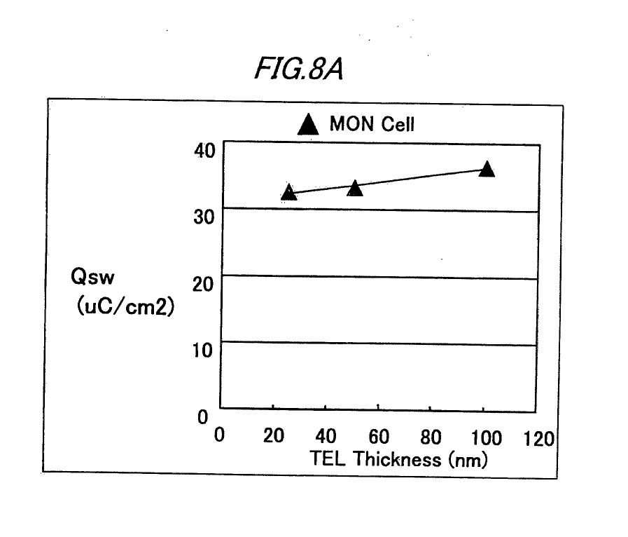

FIG. 8A shows a relationship between the film thickness of the upper electrode and the residual polarization quantity of the ferroelectric substance formed under the upper electrode. In this example, the residual polarization quantity increases together with the increase in the film thickness of the upper electrode. Thus, if the relationship between the amount of variation in the film thickness of the upper electrode and the amount of variation in the residual polarization quantity is empirically measured for several type of semiconductor device, the residual polarization quantity can be controlled in a desired direction by controlling the film thickness of the upper electrode at a point of time when predicting the residual polarization quantity before the film formation of the upper electrode.

(Ninth Method)

FIG. 8B sows a relationship between the crystallization annealing temperature of the upper electrode and the residual polarization quantity of the ferroelectric substance formed under the upper electrode. In this instance, the residual polarization quantity decreases together with a rise of the crystallization annealing temperature. Thus, if the relationship between the amount of variation in the crystallization annealing temperature of the upper electrode and the amount of variation in the residual polarization quantity is empirically measured for several type of semiconductor device, the residual polarization quantity can be controlled in a desired direction by controlling the crystallization annealing temperature of the upper electrode at a point of time when predicting the residual polarization quantity before the crystallizing anneal.

<Working Example on Planar Type Capacitor>

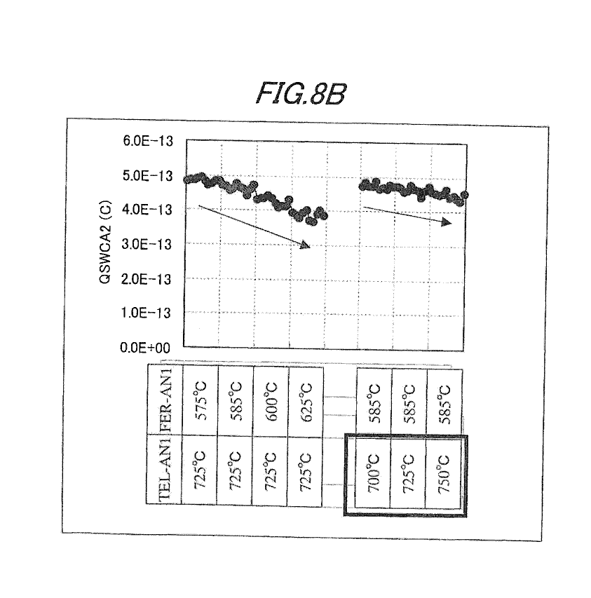

A working example, in which the present invention is applied to manufacturing a planar type capacitor, will hereinafter be described with reference to FIGS. 9 through 29.

FIG. 9 shows a process 1 (formation of a transistor layer) of a manufacturing flow. To start with, for example, an element isolation region for demarcating an element region is formed on the semiconductor substrate composed of silicon. Then, a well is formed within the semiconductor substrate formed with the element isolation region. Subsequently, the gate electrode is formed via a gate insulating film on the semiconductor substrate formed with the well. In FIG. 9, however, a gate electrode structure is illustrated as a simplified version.

A sidewall insulating film is formed at a sidewall portion of the gate electrode. A source/drain diffused layer is formed over on both sides of the gate electrode formed with the sidewall insulating film. Thus, a transistor 4 having the gate electrode and the source/drain diffused layer is formed.

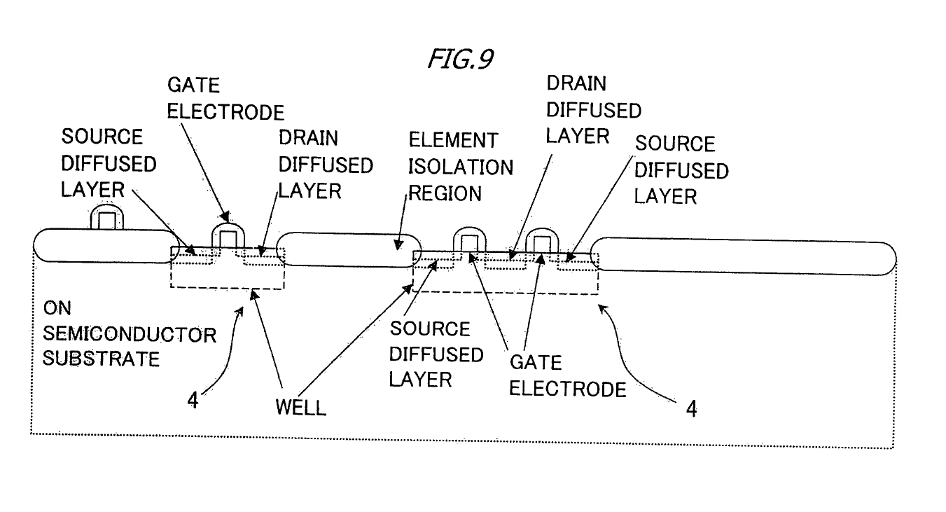

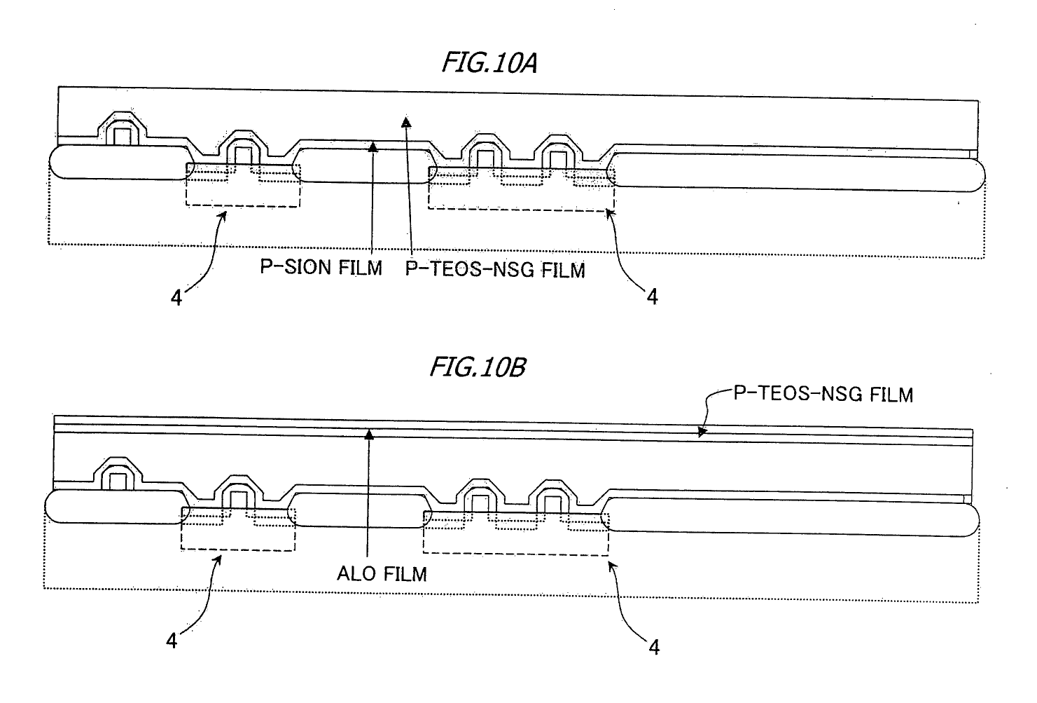

FIG. 10A shows a process 2A (formation of an inter-layer film) of the manufacturing flow. Herein, a CVD (Chemical Vapor Deposition)-based inter-layer insulating film P (plasma)-SiON (silicon oxynitride) is deposited up to 200 nm on the semiconductor substrate formed with the transistor 4. Further, a CVD-based P-TEOS (tetraeth oxysilane)-NSG (nondoped silicate glass) film is deposited up to 600 nm on the P-SiON film. Thereafter, the P-TEOS-NSG film is polished by approximately 200 nm in a CMP (Chemical Mechanical Polishing) process, thereby leveling the surface thereof.

FIG. 10B shows a process 2B (formation of an ALO film) of the manufacturing flow. Herein, for example, a CVD-based P-TEOS-NGS film is deposited up to 100 nm on the P-TEOS-NSG film. Then, a dehydration process of the P-TEOS-NSG film involves dehydrating the film, e.g., at Celsius 650 degrees, at an N₂ flow rate of 1-liter/min and for approximately 30 min. Moreover, a PVD (Physical Vapor Deposition)-based ALO film (alumina film) is deposited up to 20 nm on the P-TEOS-NSG film. Then, after forming the ALO film, e.g., a RTA (Rapid Thermal Annealing) apparatus executes the thermal treatment at Celsius 650 degrees, at an O₂ flow rate of 1-liter/min and for approximately 60 sec.

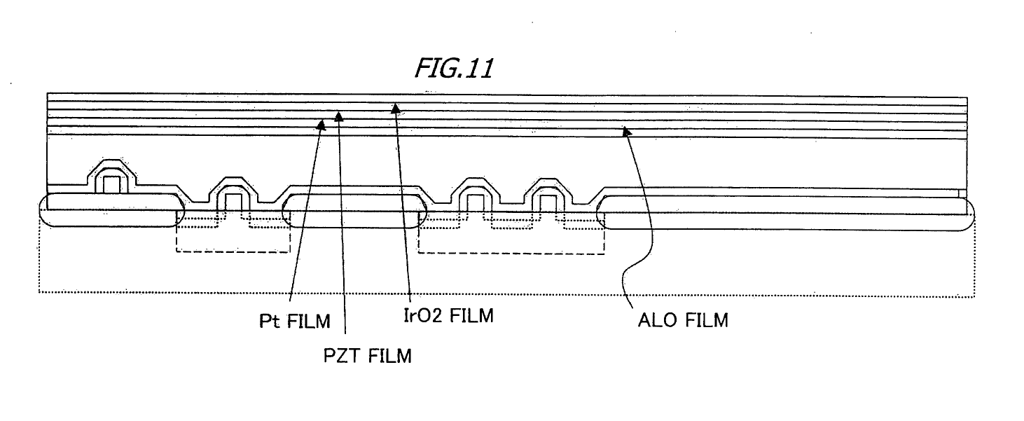

FIG. 11 shows a process 3 (formation of a pattern of the upper electrode) of the manufacturing flow. Herein, for example, a PVD (Physical Vapor Deposition)-based Pt film serving as the lower electrode is deposited up to 155 nm on the ALO film. After forming the Pt film, the orientation of the lower electrode is measured by the X-ray diffraction, thereby enabling the residual polarization quantity to be predicted.

A PVD-based PZT (lead zirconate titanate) film is deposited up to 150-200 nm over the formation of the Pt film. After forming the PZT film, the annealing process, e.g., the RTA (Rapid Thermal annealing), is executed. The annealing conditions are given such that the (annealing) temperatures is Celsius 565 degrees, an Ar flow rate is 1.95-litter/min, the O₂ flow rate is 0.055-liter/min, and the annealing time is 90 sec. In the working example, as explained in the fifth method in General Explanation of Control Procedures, the residual polarization quantity can be controlled by changing the crystallizing conditions (the annealing temperature, the annealing time and the oxygen flow rate). After annealing, the residual polarization quantity can be predicted by measuring the crystalline orientation of the PZT film or measuring the PZT film thickness by the X-ray diffraction. Further, the residual polarization quantity can be predicted from the annealing temperature. Moreover, the residual polarization quantity can be predicted from the lead quantity (manufacturing condition) in the PZT. The residual polarization quantity may also be predicted in a state of combining these physical quantities.

Next, for example, a PVD-based IrO₂ (iridium oxide) film serving as the upper electrode is deposited up to 50 nm on the PZT film. After forming the IrO₂ film, the annealing process, e.g., the RTA, is carried out. The annealing conditions are given such that, e.g., the annealing temperature is Celsius 725 degrees, the O₂ flow rate is 0.025-liter/min, and an Ar flow rate is 2-liter/min. Next, for example, the PVD-based IrO₂ film is again deposited up to 200 nm on the previous IrO₂ film. It is noted, FIG. 11 illustrates the two-layered IrO₂ films as a single layer for simplicity. The working example enables the residual polarization quantity to be controlled by controlling the reflectance of the upper electrode as described in the sixth procedure in General Explanation of Control Procedures.

At this time, the residual polarization quantity can be predicted by measuring the light reflectance and the specific resistance of the IrO₂ film serving as the upper electrode. Further, the residual polarization quantity can be also predicted by measuring the ratios of the physical characteristic quantities between the two-layered IrO₂ films. For instance, these ratios are the ratio of the light reflectance, the ratio of the specific resistance, etc between the two layers.

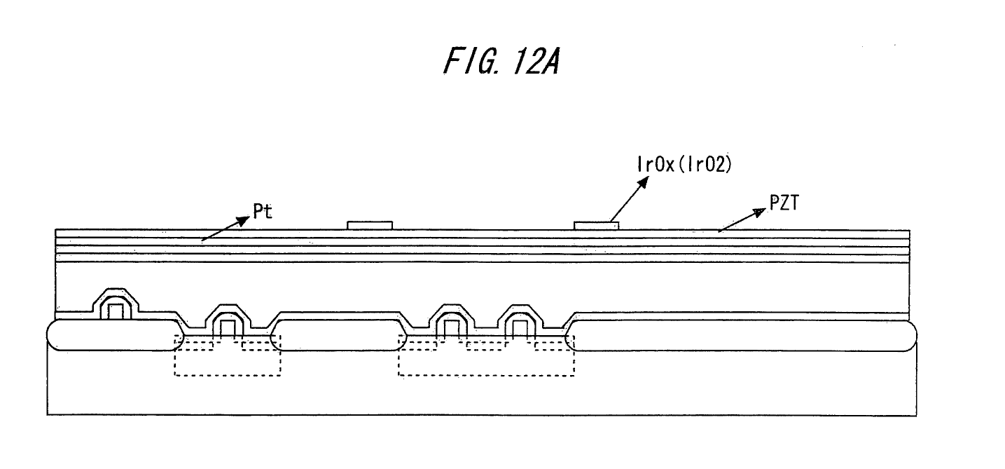

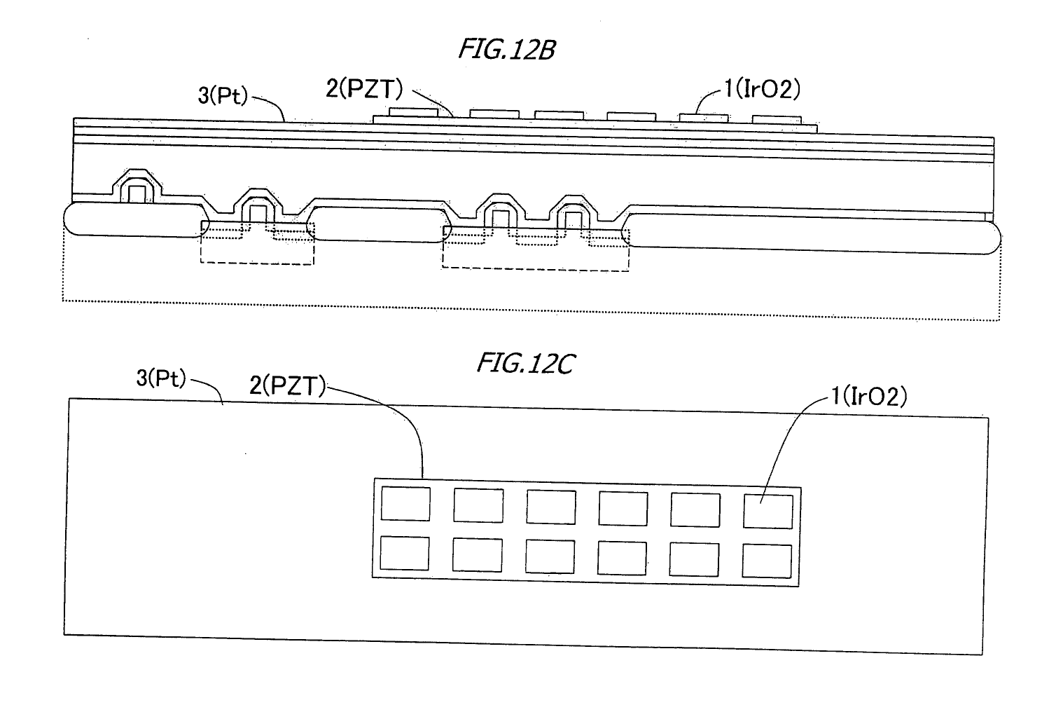

FIGS. 12A through 12C show a process 4 of the manufacturing flow. FIG. 12A is a diagram showing an etching process of the upper electrode, and FIGS. 12B and 12C are a sectional view and a plan view each showing the etching process of the ferroelectric substance.

Herein, in order to form a pattern 1 of the upper electrode, a photo resist is formed, and the IrO₂ film is etched. The residual polarization quantity can be controlled by adjusting pattern dimensions of the upper electrode at that time. The pattern dimensions (of the upper electrode) are adjusted by increasing or decreasing pattern dimensions on the reticle, and increasing or decreasing the etching quantity and the selection ratio based on the etching gas composition. A taper angle defined as an inclination, to the direction of the plane-normal line of the semiconductor substrate, of the side face of the upper electrode (IrO₂) in FIG. 12A can be controlled by controlling the etching selection ratio. As a result, the area of the upper electrode can be adjusted.

After etching the upper electrode, the area of the upper electrode is calculated by a CD-SEM (Critical Dimension-Scanning Electron Microscope) etc, and the residual polarization quantity can be thereby estimated. At this time, if the residual polarization quantity deviates from the target value, the residual polarization quantity can be further controlled under the following annealing conditions.

To be specific, the thermal treatment is carried out by use of, e.g., a vertical furnace for the recovery anneal of the PZT film. Thermal treatment conditions are normally given such that, for instance, the temperature is Celsius 650 degrees, an O₂ flow rate is 20-liter/min, and the heating time is 60 min.

Then, the formation of a pattern 2 of the ferroelectric capacitor involves forming the photo resist and etching the PZT film. FIG. 12B shows a sectional view at this time, and FIG. 12C shows a plan view thereof.

After etching the PZT film, a probe needle comes into contact with the upper electrode and the lower electrode, thus enabling the residual polarization quantity after etching the PZT film to be measured. At this time, if the residual polarization quantity deviates from the target value, the residual polarization quantity can be further controlled under the following annealing conditions.

Moreover, the thermal treatment is performed by use of, e.g., the vertical furnace for the recovery anneal of the PZT film. The thermal treatment conditions are given such that, for instance, the temperature is 350° C., the O₂ flow rate is 20-liter/min, and the heating time is 60 min. Thereafter, for protecting the PZT film, e.g., the PVD-based ALO film is deposited up to 50 nm (unillustrated) over the entire surface of the wafer. After forming the ALO film, the thermal treatment is carried out by using, e.g., the vertical furnace. The thermal treatment conditions are given such that, for instance, the temperature is 550° C., the O₂ flow rate is 20-liter/min, and the heating time is 60 min.

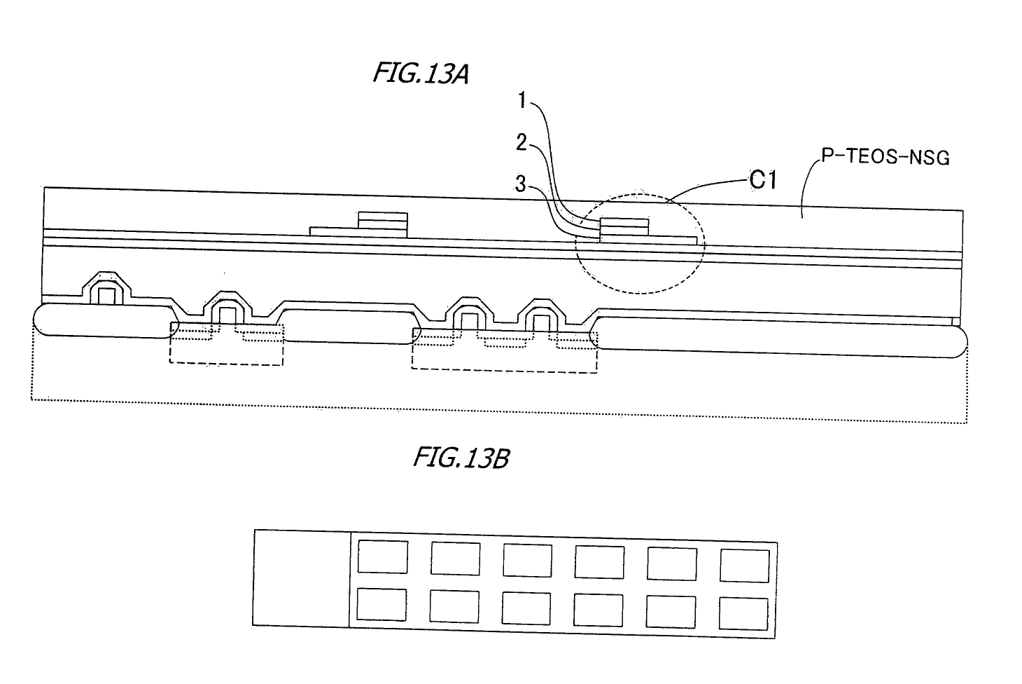

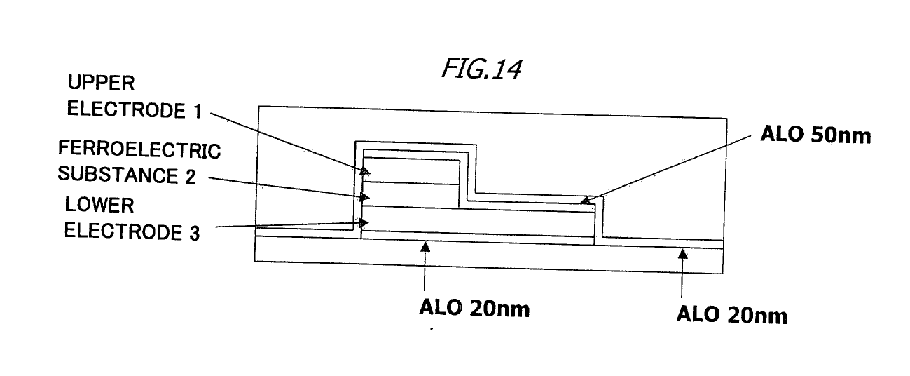

FIG. 13A shows a process 5A (formation of the inter-layer film) of the manufacturing flow. Herein, in order to form a pattern 3 of the lower electrode, the photo resist is formed, and the Pt film is etched. FIG. 13B shows a plan view at that time. The residual polarization quantity can be controlled by adjusting dimensions of the pattern 3 of the lower electrode at that time. The pattern dimensions are adjusted by any of increasing or decreasing the pattern dimensions on the reticle, and increasing or decreasing the etching quantity and the selection ratio based on the etching gas composition. A taper angle defined as an inclination, to the direction of the plane-normal line of the semiconductor substrate, of the side face of the lower electrode in FIGS. 13A and 14 can be controlled by controlling the etching selection ratio. As a result, the area of the lower electrode can be adjusted.

After etching the lower electrode, the residual polarization quantity after forming the lower electrode can be measured by making the probe come into contact with the upper electrode and the lower electrode. At this time, if the residual polarization quantity deviates from the target value, the residual polarization quantity can be further controlled under the following annealing conditions.

Namely, the thermal treatment is performed by use of, e.g., the vertical furnace for the recovery anneal of the PZT film. The thermal treatment conditions are given by standards such that, for instance, the temperature is Celsius 650 degrees, the O₂ flow rate is 20-liter/min, and the heating time is 60 min. At this time, if the measured residual polarization quantity deviates from the target value, the residual polarization quantity can be controlled by changing the annealing conditions in accordance with the procedure described in the third method in General Explanation of Control Procedures.

Thereafter, for protecting the ferroelectric capacitor, e.g., the PVD-based ALO film is deposited up to 20 nm (unillustrated) over the entire surface of the wafer. After forming the ALO film, the thermal treatment is carried out by using, e.g., the vertical furnace. The thermal treatment conditions are given such that the temperature is Celsius 550 degrees, the O₂ flow rate is 20-liter/min, and the heating time is 60 min.

Next, for example, the CVD-based P-TEOS-NSG film is deposited up to 1500 nm so as to completely cover the ferroelectric capacitor. After forming the P-TEOS-NSG film, the surface thereof is leveled by the CMP process.

FIG. 14 shows an enlarged view of the ferroelectric capacitor (corresponding to a region encircled by a circle C1 depicted by a dotted-line in FIG. 13A). The ferroelectric capacitor includes the lower electrode formed on the aluminum (ALO) film, the ferroelectric substance (PZT) on the lower electrode, and the upper electrode. Further, the side faces of the lower electrode (pattern 3) and of the ferroelectric substance (pattern 2), and the side face and the upper face of the upper electrode (pattern 1) are covered with the alumina (ALO) film.

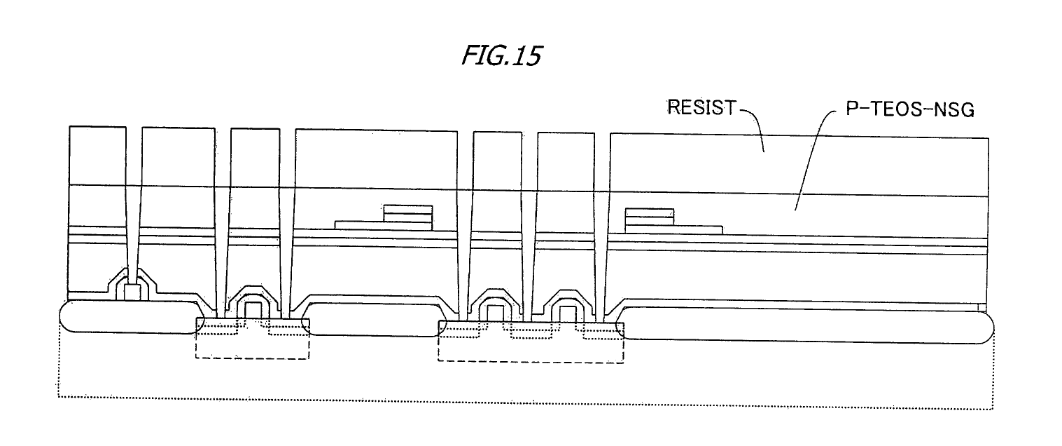

FIG. 15 shows a process 6 of the manufacturing flow. Herein, for example, the CVD apparatus conducts the plasma anneal for nitriding the surface of the P-TEOS-NSG.

The thermal treatment conditions are given such that the temperature is Celsius 350 degrees with N₂O plasma, and the heating time is 2 min. Moreover, the formation of a bulk contact involves forming a resist pattern and etching the inter-layer insulating film.

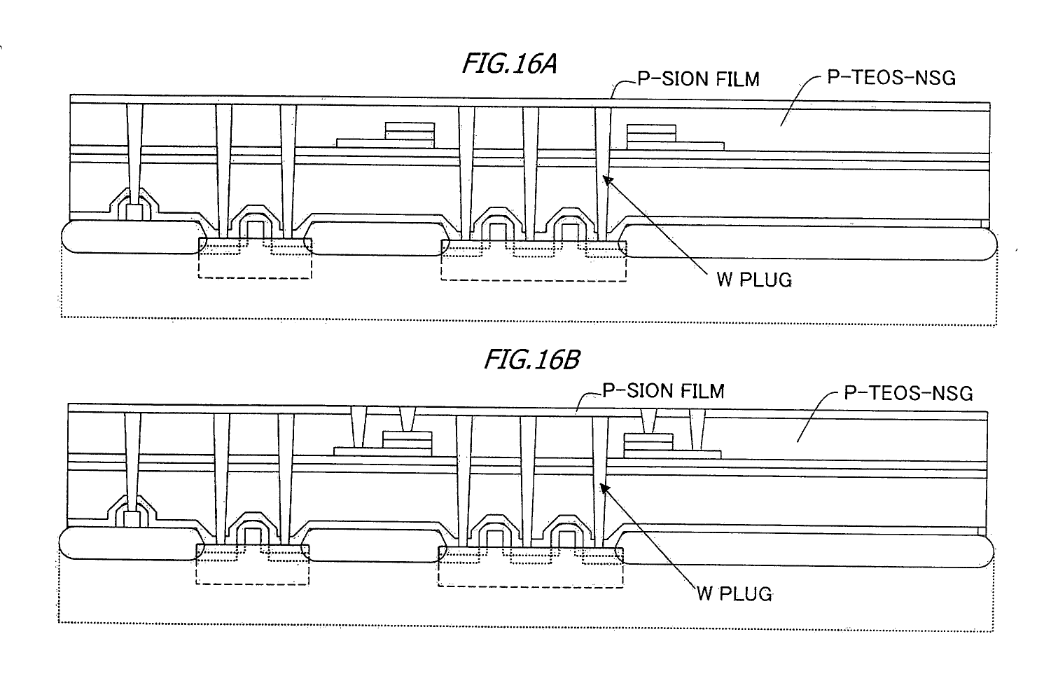

FIGS. 16A and 16B show processes 8A (formation of a W plug for a transistor) and 8B (formation of the W plug for the capacitor) of the manufacturing flow. Herein, in order to form a barrier metal of the bulk contact, Ti is deposed up to 20 nm and TiN is deposited up to 50 nm (Ti 20 nm+Tin 50 nm) (unillustrated) by, e.g., the PVD over the entire surface of the wafer. Then, after forming the barrier metal, a W film is deposited up to 50 nm by, e.g., the CVD. Moreover, the W film is polished by, e.g., the CMP process for removing the W film other than the bulk contact (W plug). Next, for example, the CVD apparatus performs the plasma anneal in order to nitride the surface of the P-TEOS-NSG. The thermal treatment conditions are given such that the temperature is Celsius 350 degrees and the heating time is 2 min in a N₂O plasma atmosphere. Further, a P-SiON film is deposited up to 100 nm by, e.g., the CVD.

Next, the formation of a contact for the upper electrode and the lower electrode involves forming a resist pattern on the P-SiON film (unillustrated). Then, as illustrated in FIG. 16B, with the resist pattern serving as a mask, a contact hole for the upper electrode and the lower electrode is formed by etching. Further, the thermal treatment is performed by use of, e.g., the vertical furnace for the recovery anneal of the PZT film. The thermal treatment conditions are given such that, for instance, the temperature is Celsius 500 degrees, the O₂ flow rate is 20-liter/min, and the heating time is 60 min.

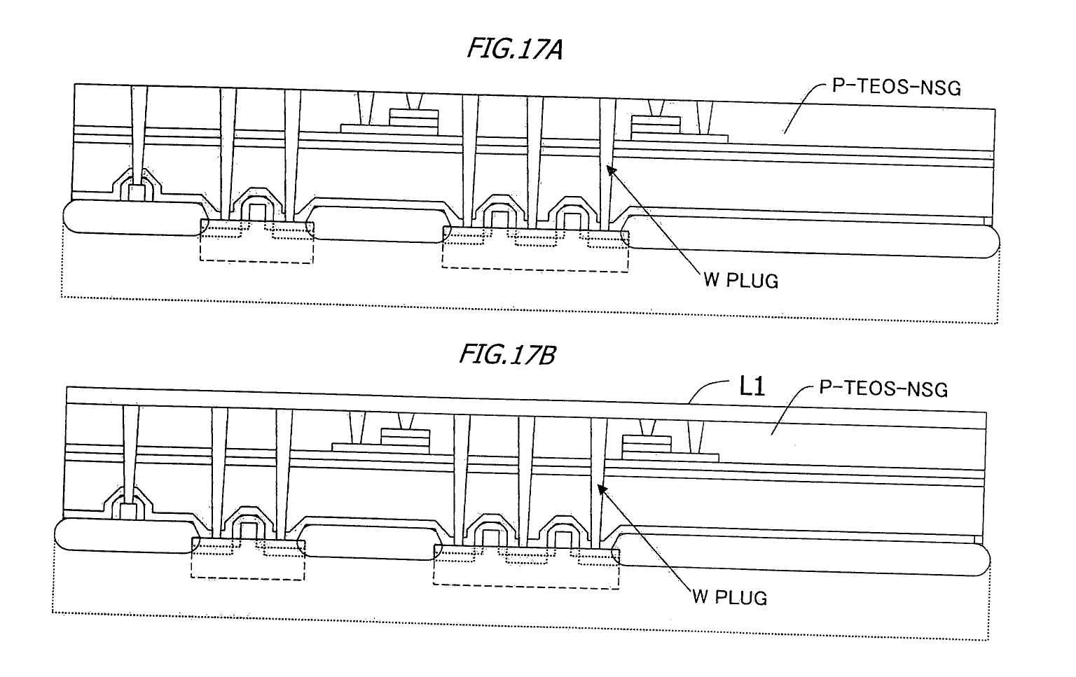

FIGS. 17A and 17B show processes 9A (removal of a P-SiON film) and 9B (film formation of a first wiring layer) of the manufacturing flow. Herein, an entire surface of the P-SiON film is etched back by, e.g., an etching process for removing the P-SiON film.

Next, as shown in FIG. 17B, the formation of a first wiring layer involves forming stacked films composed of TiN deposited up to 150 nm, Al—Cu deposited up to 550 nm, Ti deposited up to 5 nm and TiN deposited up to 150 nm (TiN 150 nm+Al—Cu 550 nm+Ti 5 nm+TiN 150 nm) by, e.g., the PVD. In FIG. 17B, however, the stacked films are omitted in illustration but are shown as a first wiring layer L1 (of which a pattern is not yet formed).

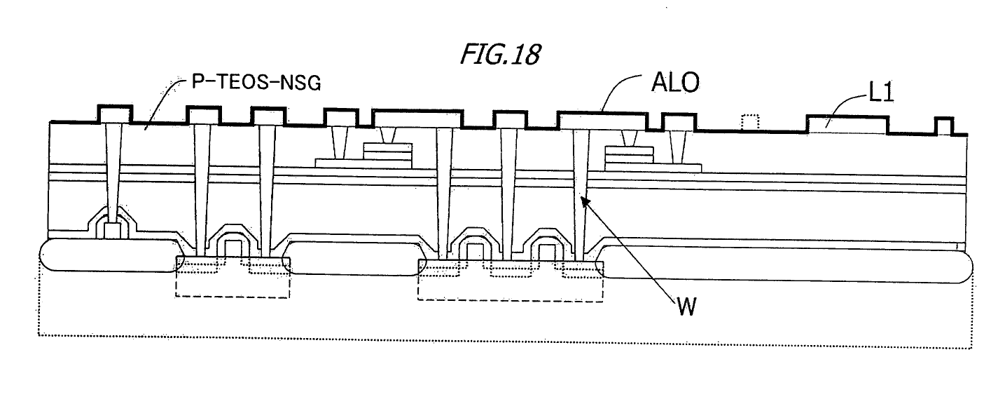

FIG. 18 shows a process 10 (patterning of the first wiring layer) of the manufacturing flow. Herein, for forming the pattern of the first wiring layer L1, a resist pattern (unillustrated) is formed, and the first wiring layer is etched in a way that uses the resist pattern as a mask. Further, after forming the pattern of the first wiring layer L1, the thermal treatment is carried out by use of, e.g., the vertical furnace, wherein the temperature is Celsius 350 degrees, a N₂ flow rate is 20-liter/min, and the heating time is 30 min. Moreover, the ALO film is deposited up to 20 nm by, e.g., the PVD on the first wiring layer and on the P-TEOS-NSG film. The ALO film functions as a barrier film against the hydrogen and moisture.

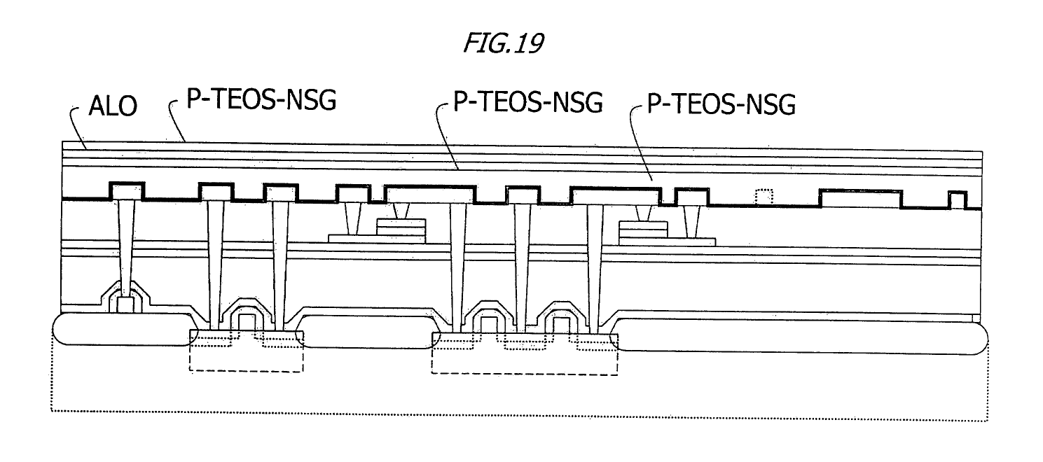

FIG. 19 shows a process 11 of the manufacturing flow. Herein, the P-TEOS-NSG film is deposited up to 2600 nm by, e.g., the CVD on the ALO film, then for leveling the whole, the P-TEOS-NSG film is polished by, e.g., the CMP process, and the wafer surface is leveled.

Moreover, for example, the CVD apparatus performs the plasma anneal in order to nitride the surface of the P-TEOS-NSG. The annealing conditions are given such that the annealing temperature is Celsius 350 degrees and the annealing time is 4 min in, e.g., the N₂O plasma atmosphere. Then, the P-TEOS-NSG film is again deposited up to 100 nm by, e.g., the CVD.

Still further, the ALO film is deposited up to 50 nm by, e.g., the PVD on the P-TEOS-NSG film. The P-TEOS-NSG film is deposited up to 100 nm by, e.g., the CVD on the ALO film. For nitriding the surface of the P-TEOS-NSG, e.g., the CVD apparatus conducts the plasma anneal. The annealing conditions are given such that the annealing temperature is Celsius 350 degrees and the annealing time is 2 min in the N₂O plasma atmosphere.

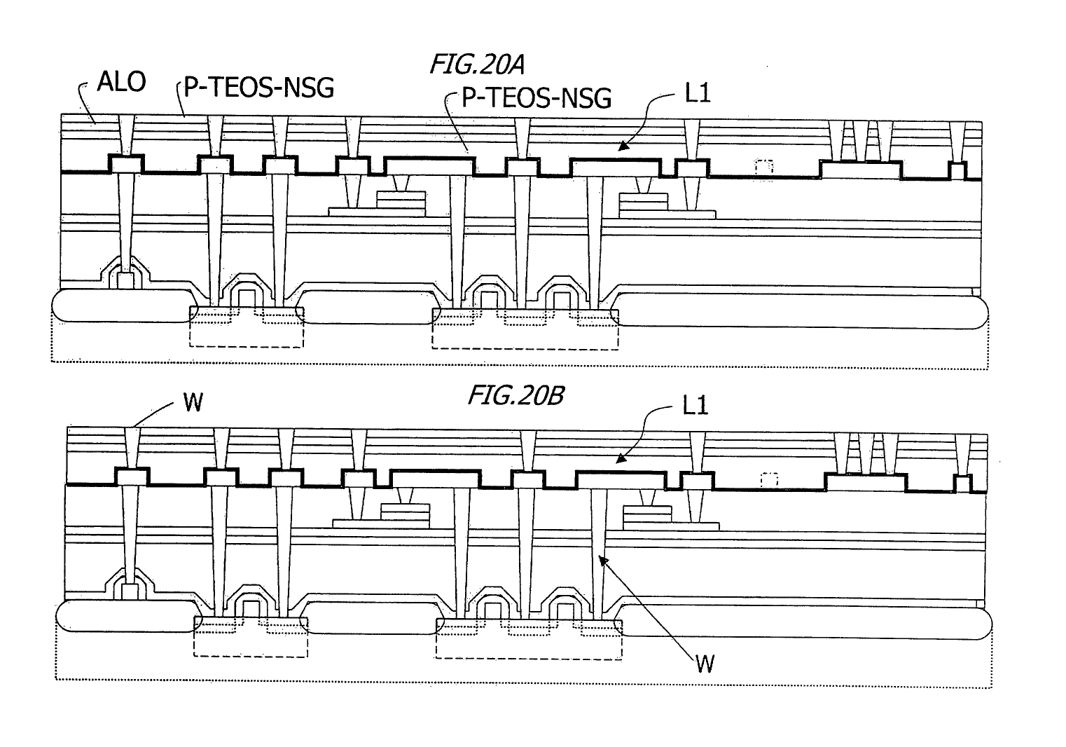

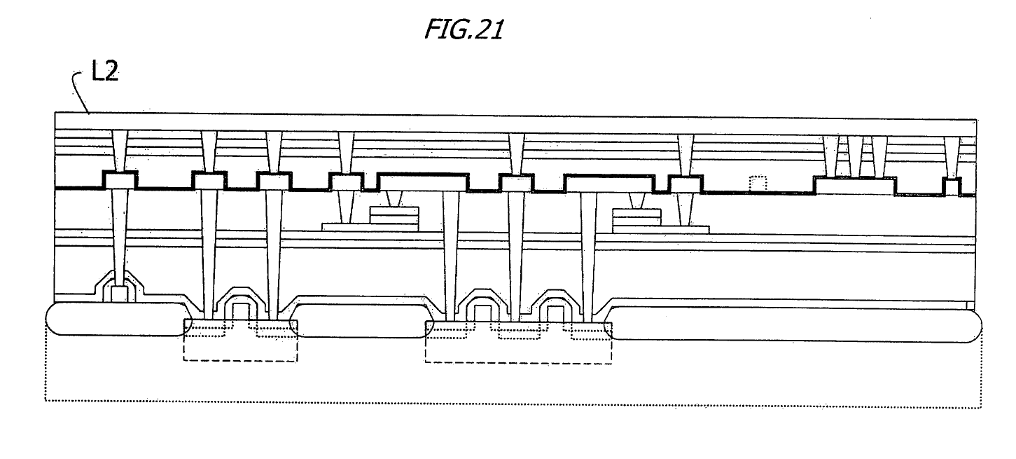

FIGS. 20A and 20B show processes 12A and 12B of the manufacturing flow. Herein, the resist pattern is formed (unillustrated) for forming the contact hole that connects the first wiring layer L1 and a second wiring layer L2 (FIG. 21) to each other. Further, with the resist pattern serving as the mask, the inter-layer insulating film P-TEOS-NSG film and the ALO film are etched by, e.g., the etching process.

Next, the formation of a contact plug that connects the first wiring layer L1 and the second wiring layer L2 involves, at first, depositing the TiN film up to 50 nm by, e.g., the PVD over the entire surface of the wafer in order to provide the barrier metal (unillustrated) Moreover, the W film is deposited up to 650 nm by, e.g., the CVD on the TiN film. Then, for providing the contact plug, the entire surface of W film is etched back by, e.g., the etching process. As a substitute for the etching, however, the CMP polishing may also be carried out.

FIG. 21 shows a process 13 of the manufacturing flow. Herein, in order to form the second wiring layer L2, stacked films composed of Al—Cu deposited up to 550 nm, Ti deposited up to 5 nm and TiN deposited up to 150 nm (Al—Cu 550 nm+Ti 5 nm+TiN 150 nm) by, e.g., the PVD. In FIG. 21, however, the stacked films are omitted in illustration but are shown as the second wiring layer (of which the pattern is not yet formed).

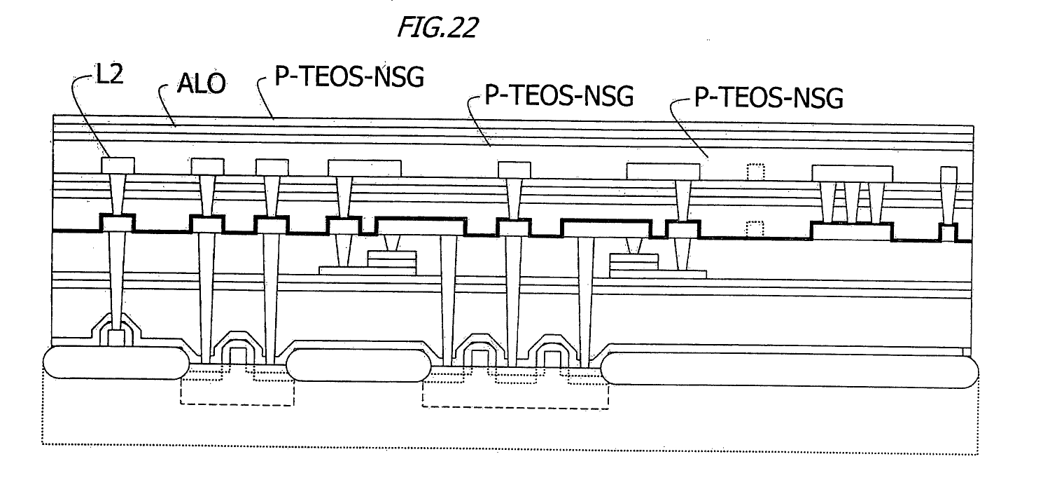

FIG. 22 shows a process 14 of the manufacturing flow. Herein, the formation of the second wiring layer L2 involves forming the resist pattern (unillustrated) and, with the resist pattern serving as the mask, etching the second wiring layer. Furthermore, the P-TEOS-NSG film is deposited up to 2200 nm by, e.g., the CVD on the second wiring layer, then for leveling the whole, the P-TEOS-NSG film is polished by, e.g., the CMP process, and the wafer surface is leveled.

Moreover, for nitriding the surface of the P-TEOS-NSG, e.g., the CVD apparatus conducts the plasma anneal. The annealing conditions are given such that the annealing temperature is Celsius 350 degrees and the annealing time is 4 min in the N₂O plasma atmosphere. The P-TEOS-NSG film is again deposited up to 100 nm by, e.g., the CVD on the previous P-TEOS-NSG film. Then, for nitriding the surface of the P-TEOS-NSG, for example, the CVD apparatus performs the plasma anneal. The annealing conditions are given such that the annealing temperature is 350° C. and the annealing time is 2 min in the N₂O plasma atmosphere.

Next, the ALO film is deposited up to 50 nm by, e.g., the PVD on the P-TEOS-NSG film. The P-TEOS-NSG film is again deposited up to 100 nm by, e.g., the CVD on the ALO film. For nitriding the surface of the P-TEOS-NSG, e.g., the CVD apparatus conducts the plasma anneal. The annealing conditions are given such that, for example, the annealing temperature is 350° C. and the annealing time is 2 min in the N₂O plasma atmosphere.

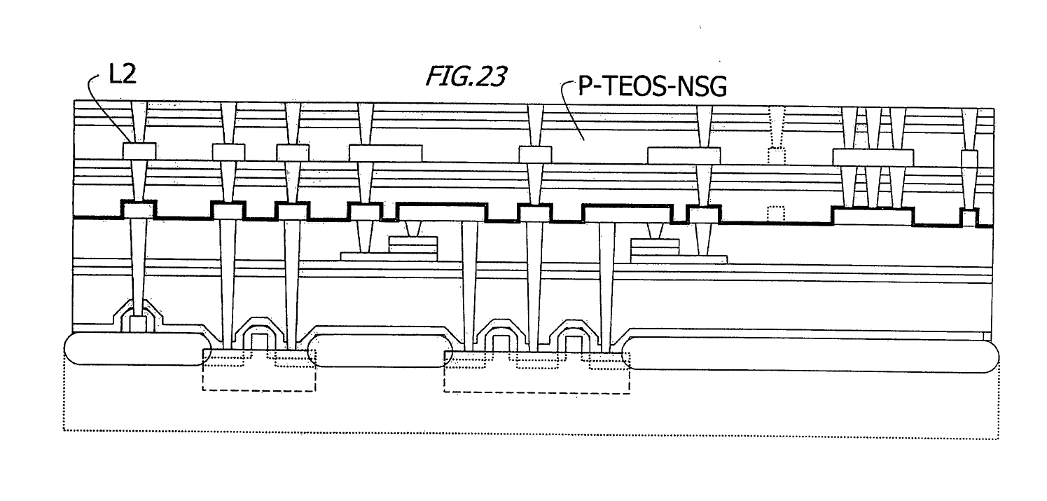

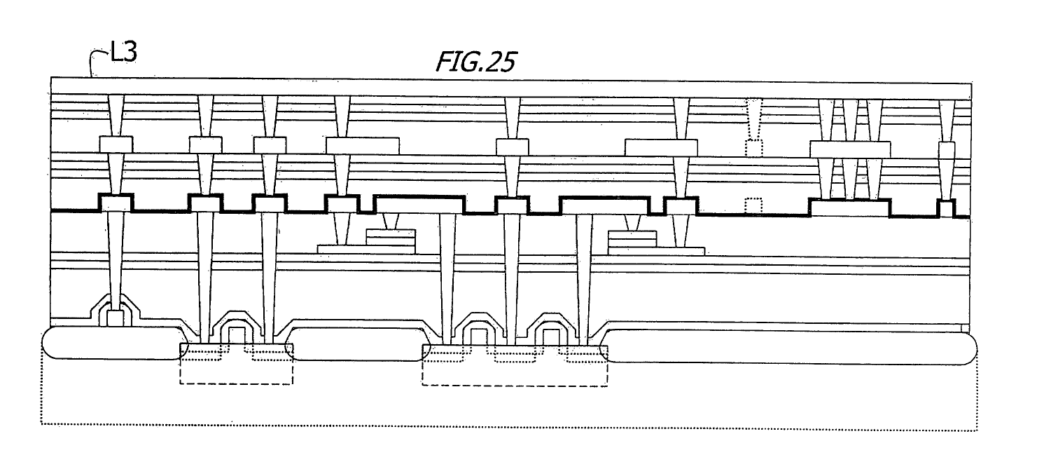

FIG. 23 shows a process 15 (formation of the contact hole) of the manufacturing flow. Herein, at first, the resist pattern (not shown) is formed in order to provide the contact hole that connects the second wiring layer L2 and a third wiring layer L3 (FIG. 25) to each other. Then, with the resist pattern serving as the mask, the inter-layer insulating film P-TEOS-NSG film is etched by, e.g., the etching process.

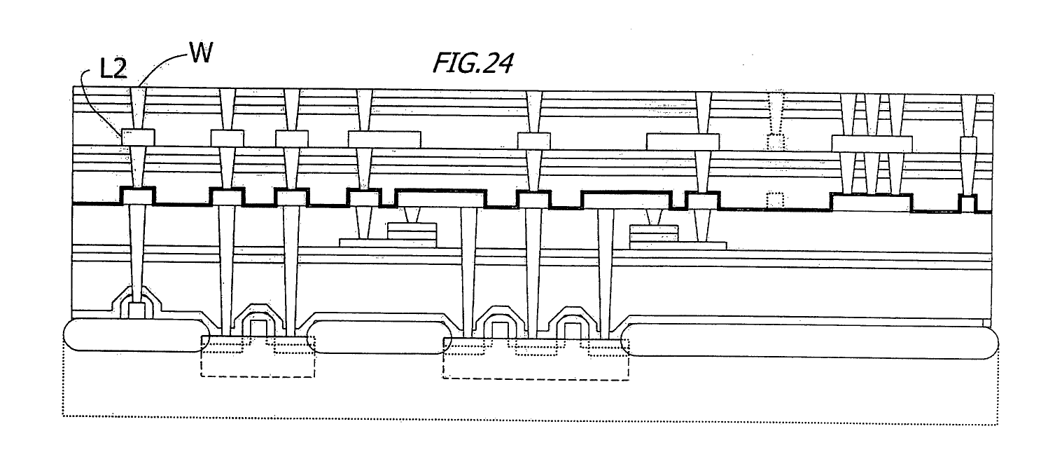

FIG. 24 shows a process 16 (formation of the W plug) of the manufacturing flow. Herein, to begin with, the TiN film is deposited up to 50 nm (not shown) over the entire surface of the wafer by, e.g., the PVD for providing the barrier metal in order to form the contact plug that connects the second wiring layer L2 and the third wiring layer L3 to each other. Then, the W film is deposited up to 650 nm by, e.g., the CVD on the TiN film. Further, the W film is etched back by, e.g., the etching process for providing the contact plug. As a substitute for the etching, however, the CMP polishing may also be carried out.

FIG. 25 shows a process 17 (film formation of a third wiring layer) of the manufacturing flow. Herein, for forming the third wiring layer L3, stacked films composed of Al—Cu deposited up to 500 nm and TiN deposited up to 150 nm (Al—Cu 500 nm+TiN 150 nm) by, e.g., the PVD. In FIG. 25, however, the stacked films are omitted in illustration but are shown as the third wiring layer L3 (of which the pattern is not yet formed).

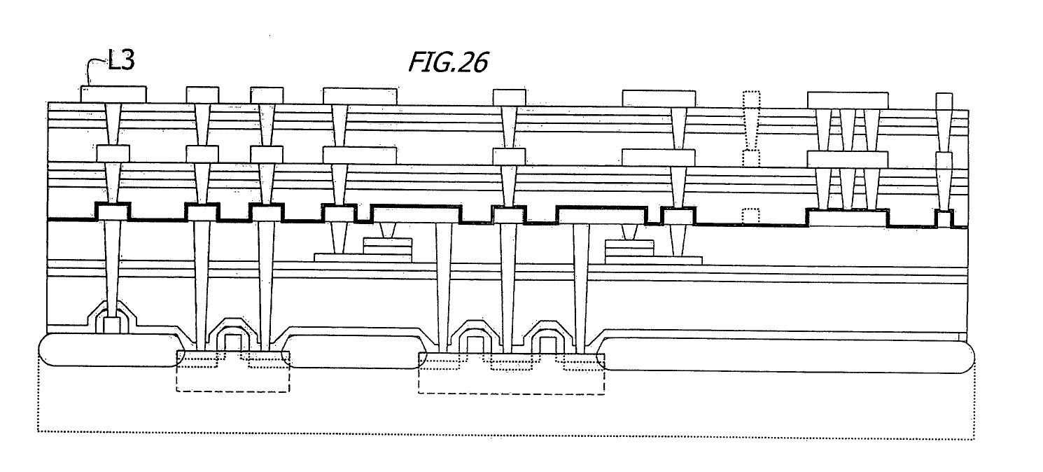

FIG. 26 shows a process 18 (patterning of the second wiring layer) of the manufacturing flow. Herein, the formation of the third wiring layer involves forming the resist pattern and, with the resist pattern (unillustrated) serving as the mask, etching the third wiring layer L3.

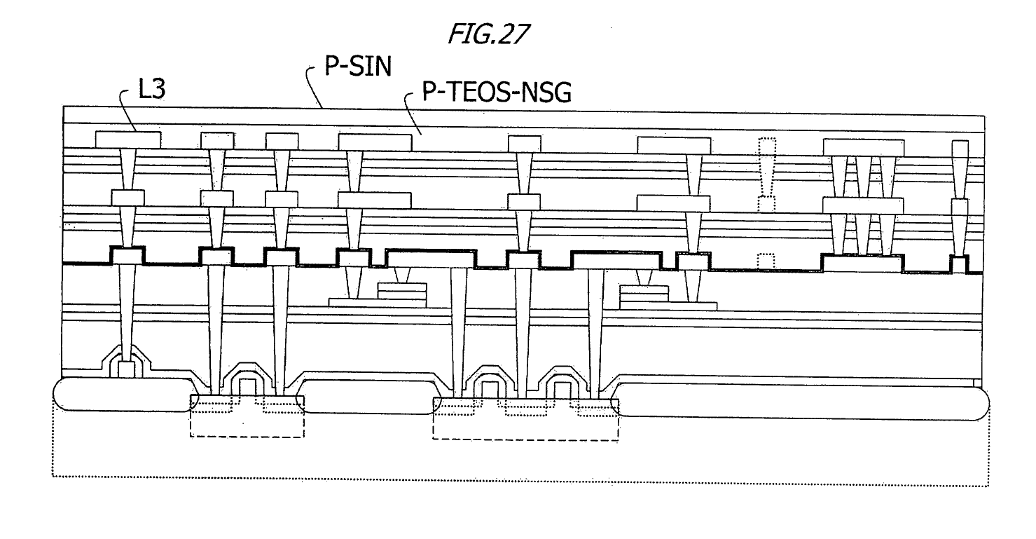

FIG. 27 shows a process 19 (formation of P-SiN film) of the manufacturing flow. Herein, the P-TEOS-NSG film is deposited as a passivation film up to 100 nm by, e.g., the CVD on the third wiring layer L3. Moreover, for nitriding the surface of the P-TEOS-NSG, e.g., the CVD apparatus conducts the plasma anneal. The annealing conditions are given such that, for example, the annealing temperature is Celsius 350 degrees and the annealing time is 2 min in the N₂O plasma atmosphere. Further, a P (plasma)-SiN (silicon nitride) film is deposited as the passivation film up to 350 nm on the P-TEOS-NSG film.

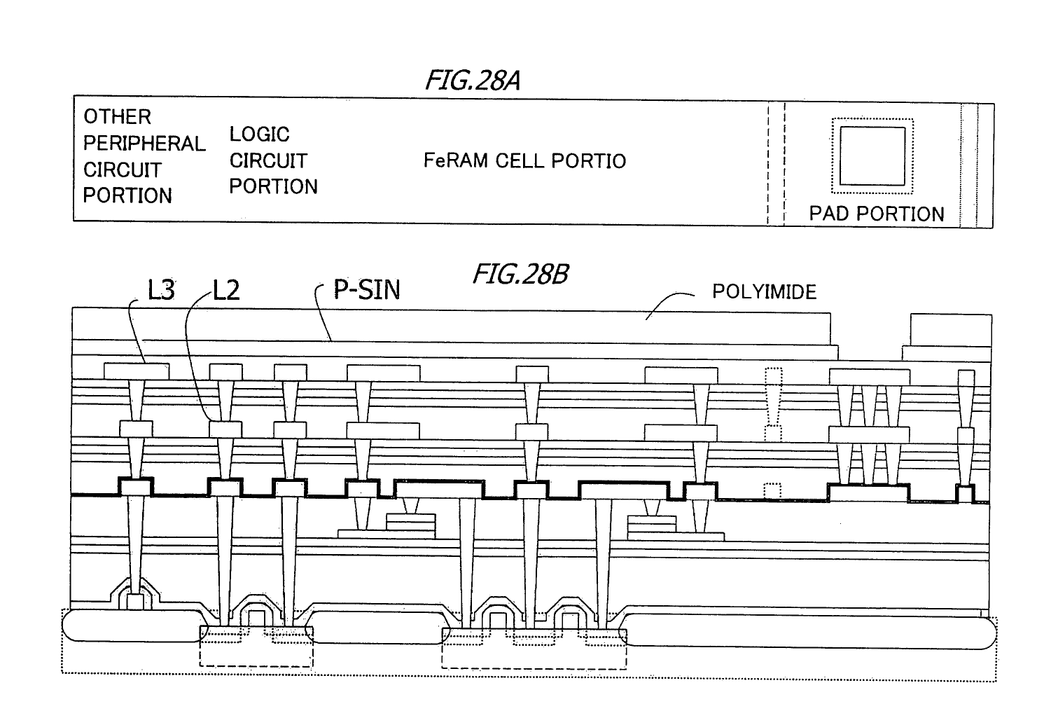

FIGS. 28A and 28B show a process 20 (formation of the protection film) of the manufacturing flow. FIG. 28A is a view as viewed from the upper face of the substrate, and FIG. 28B is a sectional view. Herein, the resist pattern is formed on the P-SiN film in order to form PAD.

With the resist pattern (unillustrated) serving as the mask, the PAD portion is etched. The etching process involves etching the P-TEOS-NSG film and the P-SiN film, and simultaneously etching the upper TiN film, having the thickness of 150 nm, of the stacked films of the third wiring layer L3.

After forming the PAD, photosensitive polyimide is coated as a protection film up to 3 μm (in the case of using non-photosensitive polyimide, the resist pattern is formed on the non-photosensitive polyimide, and the non-photosensitive polyimide is dissolved by a dedicated developing solution), thus forming the protection film so as to protect the area other than the PAD portion. After forming (coating) the polyimide, the thermal treatment is conducted by, e.g., a horizontal furnace at 310° C. with the N₂ flow rate of 100-liter/min for 40 min, thereby hardening the polyimide.

At this time, as described in the fourth method in General Explanation of Control Procedures, the residual polarization quantity can be controlled by changing the thermal treatment conditions.

Note that the explanatory examples have dealt with the general type of planar ferroelectric capacitor, however, the control method having the concept described above can be applied without any problems even when different in terms of the manufacturing method of manufacturing the planar type ferroelectric capacitor.

<Working Example on Stack Type Capacitor>

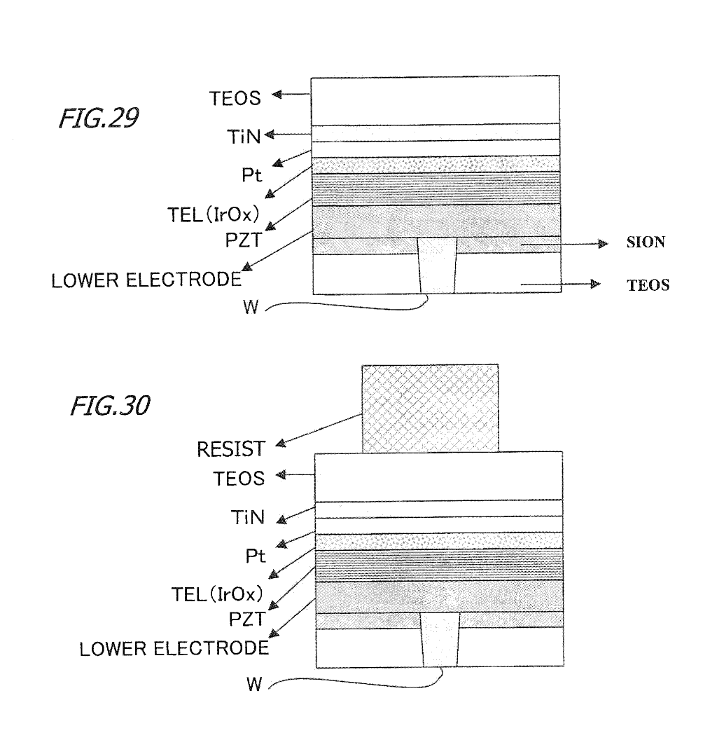

FIGS. 29 through 38 show an example of applying to the semiconductor device including a stack type capacitor. An assumption in FIG. 29 is that the formation of the lower electrode, the ferroelectric substance (PZT) and the upper electrode (the TEL (IrOx), the Pt layer, the TiN layer and the TEOS layer) has already been finished. Similarly to the case of the planar type capacitor, however, the residual polarization quantity may be controlled by predicting the residual polarization quantity from the physical quantities of the lower electrode, the ferroelectric substance layer and the upper electrode and by controlling the manufacturing conditions (the crystallization annealing condition, the recovery annealing condition, the reflectance of the upper electrode, and the specific resistance).

FIG. 30 shows a resist forming process. To be specific, the resist is coated over the TEOS film, and the resist pattern is formed by photolithography. At this time, a quantity of a dimensional change of the resist pattern is determined based on the residual polarization quantity predicted from the physical quantities in the process before the TEOS forming process. The dimensional change may be done by changing, e.g., dimensions of a mask pattern of the photolithography. Further, in the case of employing a standard mask (a mask having the normal dimensions), the exposure quantity may also be changed.

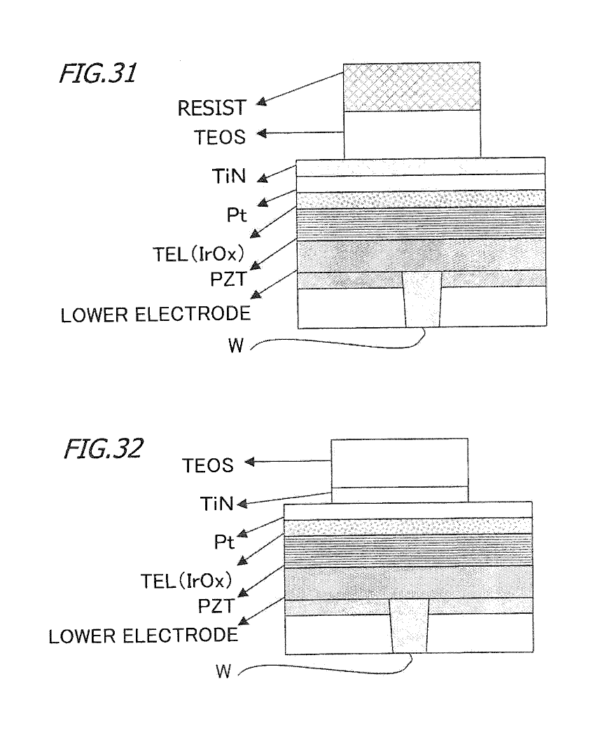

FIGS. 31 through 34 show the pattern forming processes of the upper electrode and the lower electrode. As in FIG. 31, the TEOS is etched with the resist serving as the mask. Next, as in FIG. 32, the TiN film is etched with the resist serving as the mask.

Moreover, as illustrated in FIG. 33, the Pt film, the TEL (IrOx), the ferroelectric substance (PZT) and the lower electrode are etched with the TiN film serving as the mask. Then, the TiN film is peeled off by wet etching. The ferroelectric capacitor is thereby pattern-formed.

At this time, the selection ratio based on the etching quantity and the etching gas composition may also be controlled. The taper angle defined as an inclination, to the direction of the plane-normal line of the semiconductor substrate, of the side face of the upper electrode or the lower electrode can be controlled by controlling the etching selection ratio. As a result, the area of the upper electrode or the lower electrode can be adjusted.

After forming the lower electrode, the probe comes into contact with an unillustrated lower wiring connected to a tungsten layer and with the upper electrode, thus measuring the residual polarization quantity of the ferroelectric capacitor. Then, if the measured value deviates from the range of the target value, the residual polarization quantity may be controlled in the process of the upper layer. For example, the thermal treatment conditions may be changed in the thermal treatment process of the upper electrode.

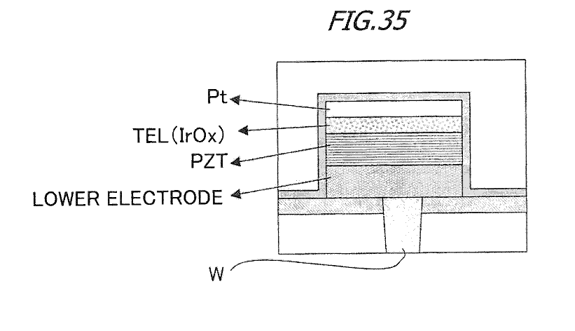

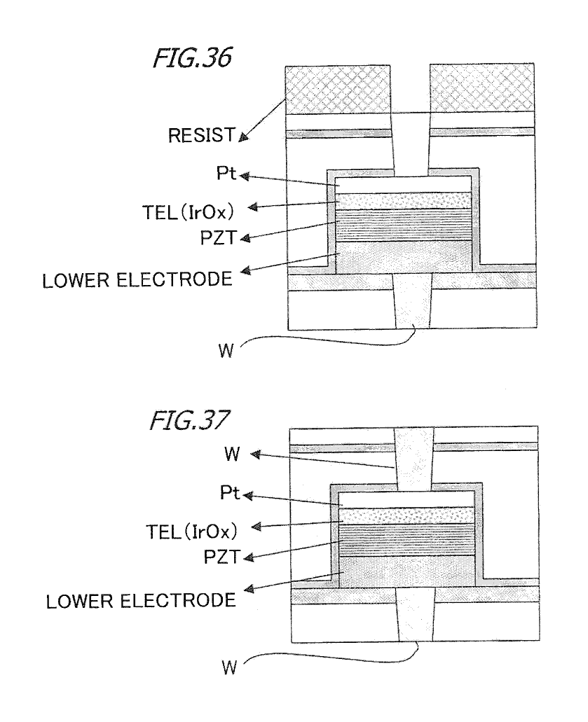

FIG. 35 shows an aluminum (ALO) film forming process and an inter-layer insulating film forming process. The ALO film functions as the barrier film against the hydrogen and the moisture. Further FIGS. 36 and 37 show a patterning process of the plug layer (a patterning process of the hole layer) on the side of the upper electrode and a tungsten plug forming process. The subsequent procedures are the same as in the case of the planar type capacitor.

As described above, in the stack type capacitor also, the residual polarization quantity of the ferroelectric capacitor is predicted or measured, and the manufacturing conditions in the subsequent process are controlled, thereby enabling the residual polarization quantity to be controlled.

In the processes in FIGS. 29-34, the upper electrode pattern and the lower electrode pattern are formed by etching with the same TiN film serving as the mask. The implementation of the present invention is not, however, limited to those processes, and the upper electrode and the lower electrode may also be etched by use of different masks. In this case, it may suffice that the dimensions of the upper electrode pattern are changed based on the residual polarization quantity predicted before forming the pattern of the upper electrode.

Then, after forming the upper electrode, further, the residual polarization quantity may be controlled by measuring the residual polarization quantity and changing the etching conditions of the lower electrode from the measured result thereof. Namely, in the stack type capacitor also, the residual polarization quantity can be controlled by use of any one of the control procedures of the residual polarization quantity explained in FIG. 1.

What is claimed is:

1. A semiconductor device manufacturing method comprising:
forming a transistor layer portion on a semiconductor substrate; and
forming a ferroelectric capacitor portion including a lower electrode, a ferroelectric substance and an upper electrode above the transistor layer portion,
wherein the forming the ferroelectric capacitor portion includes adjusting an area of the upper electrode on the basis of manufacturing parameters of the ferroelectric capacitor portion.

2. The semiconductor device manufacturing method according to claim 1, wherein the adjusting includes forming, if a predicted value of a residual polarization quantity of the ferroelectric capacitor portion based on the manufacturing parameters of the ferroelectric capacitor portion is smaller than a target value, the area of the upper larger than a usual value.

3. The semiconductor device manufacturing method according to claim 1, wherein the adjusting includes forming, if the predicted value of the residual polarization quantity of the ferroelectric capacitor portion based on the manufacturing parameters of the ferroelectric capacitor portion is larger than the target value, the area of the upper electrode smaller than at a usual value.

4. The semiconductor device manufacturing method according to claim 1, wherein if the predicted value of the residual polarization quantity of the ferroelectric capacitor portion is smaller than the target value, the upper electrode is formed in a way that increases a selection ratio of an etching process of the upper electrode and decreases a taper angle defined as an inclination of a side face of the upper electrode to a direction of a plane-normal line of the semiconductor substrate.

5. The semiconductor device manufacturing method according to claim 1, wherein if the predicted value of the residual polarization quantity of the ferroelectric capacitor portion is larger than the target value, the upper electrode is formed in a way that decreases the selection ratio of then etching process of the upper electrode and increases the taper angle defined as the inclination of a side face of the upper electrode to a direction of the plane-normal line of the semiconductor substrate.

6. A semiconductor device manufacturing method comprising:
forming a transistor layer portion on a semiconductor substrate; and
forming a ferroelectric capacitor portion including a lower electrode, a ferroelectric substance and an upper electrode above the transistor layer portion,
wherein the forming the ferroelectric capacitor portion includes:
forming a film of the lower electrode;
forming a film of the ferroelectric substance;
forming a film of the upper electrode;
forming a pattern of the upper electrode;
measuring a residual polarization quantity of the ferroelectric substance; and
forming a shape (pattern) of the lower electrode,
wherein the forming the pattern of the lower electrode includes decreasing an area of the lower electrode to a greater degree than a usual value if a measured value of the residual polarization quantity is larger than a target value, and increasing the area of the lower electrode to a greater degree than the normal value if the measured value of the residual polarization quantity is smaller than the target value.

7. The semiconductor device manufacturing method according to claim 6, wherein the area of the lower electrode is adjusted by at least one selected from a group of consisting of a resist area and an etching condition for etching the lower electrode when forming the lower electrode.

8. The semiconductor device manufacturing method according to claim 6, wherein the forming the ferroelectric capacitor portion further includes controlling an annealing temperature for recovering the ferroelectric capacitor portion from a damage accompanying the formation of the pattern of the upper electrode or the lower electrode in accordance with the measured value of the residual polarization quantity of the ferroelectric capacitor portion.

9. The semiconductor device manufacturing method according to claim 8, wherein the controlling the annealing temperature includes, if the measured value of the residual polarization quantity is larger than the target value, at least one selected from a group of consisting of a process of increasing a recovery annealing temperature to a greater degree than a reference temperature, a process of making a period of recovery annealing time longer than a period of reference time, and a process of increasing an oxygen flow rate when in the recovery anneal to a greater degree than a reference flow rate.

10. The semiconductor device manufacturing method according to claim 8, wherein the controlling an annealing temperature includes, if the measured value of the residual polarization quantity is smaller than the target value, at least one selected from a group of consisting of a process of decreasing a recovery annealing temperature to a greater degree than a reference temperature, a process of making a period of recovery annealing time shorter than a period of reference time, and a process of decreasing an oxygen flow rate when in the recovery anneal to a greater degree than a reference flow rate.

11. A semiconductor device manufacturing method comprising:
forming a transistor layer portion on a semiconductor substrate;
forming a ferroelectric capacitor portion above the transistor layer portion;
forming a wiring layer above the ferroelectric capacitor portion; and
changing a thermal treatment condition of polyimide in accordance with a measured value of a residual polarization quantity after forming the wiring layer.

12. The semiconductor device manufacturing method according to claim 11, wherein the changing includes, if the measured value of the residual polarization quantity is larger than a target value and if a single-layered or more-layered hydrogen/moisture barrier film exist at least under the polyimide layer but above the ferroelectric capacitor portion, a process of decreasing a thermal treatment temperature of the polyimide to a greater degree than a reference temperature, or a process of decreasing a period of thermal treatment time of the polyimide to a greater degree than a period of reference time.

13. The semiconductor device manufacturing method according to claim 11, wherein the changing includes, if the measured value of the residual polarization quantity is smaller than a target value and if a single-layered or more-layered hydrogen/moisture barrier film exist at least under the polyimide layer but above the ferroelectric capacitor portion, a process of increasing a thermal treatment temperature of the polyimide to a greater degree than a reference temperature, or a process of increasing a period of thermal treatment time of the polyimide to a greater degree than a period of reference time.

14. The semiconductor device manufacturing method according to claim 11, wherein the changing includes, if the measured value of the residual polarization quantity is larger than the target value and if a hydrogen/moisture barrier film does not exist at least under the polyimide layer, a process of increasing a thermal treatment temperature of the polyimide to a greater degree than a reference temperature, or a process of increasing a period of thermal treatment time of the polyimide to a greater degree than a period of reference time.

15. The semiconductor device manufacturing method according to claim 11, wherein the changing includes, if the measured value of the residual polarization quantity is smaller than the target value and if a hydrogen/moisture barrier film does not exist at least under the polyimide layer, a process of decreasing a thermal treatment temperature of the polyimide to a greater degree than a reference temperature, or a process of decreasing a period of thermal treatment time of the polyimide to a greater degree than a period of reference time.

16. A semiconductor device manufacturing method comprising:
forming a transistor layer portion on a semiconductor substrate; and
forming a PZT ferroelectric capacitor portion above the transistor layer portion,
wherein the forming the PZT ferroelectric capacitor portion includes controlling a crystallization annealing temperature of a ferroelectric substance and an oxygen flow rate when in crystallizing anneal in accordance with a combination of a content of lead in a PZT ferroelectric substance and a film thickness of the PZT ferroelectric substance.

17. The semiconductor device manufacturing method according to claim 16, wherein the controlling includes, if the combination of the content of lead in the PZT ferroelectric substance and the film thickness of the PZT ferroelectric substance is such a combination that a residual polarization quantity of the ferroelectric capacitor portion is larger than a target value, executing at least one selected from a group of consisting of control of setting the crystallization annealing temperature for crystallizing the ferroelectric substance higher than a reference value, and control of increasing the oxygen flow rate when in the crystallizing anneal.

18. The semiconductor device manufacturing method according to claim 16, wherein the controlling includes, if the combination of the content of lead in the PZT ferroelectric substance and the film thickness of the PZT ferroelectric substance is such a combination that the residual polarization quantity of the PZT ferroelectric capacitor portion is smaller than the target value, executing at least one selected from a group of consisting of control of setting the crystallization annealing temperature for crystallizing the ferroelectric substance lower than a reference value, and control of decreasing the oxygen flow rate when in the crystallizing anneal.

19. The semiconductor device manufacturing method comprising:
forming a transistor layer portion on a semiconductor substrate; and
forming a PZT ferroelectric capacitor portion above the transistor layer portion,
wherein the forming the PZT ferroelectric capacitor portion includes: controlling a crystallization annealing temperature of a PZT ferroelectric substance and an oxygen flow rate when in crystallizing anneal in accordance with a combination of a content of lead in the PZT ferroelectric substance and a film thickness of the PZT ferroelectric substance; and a step forming an upper electrode of the PZT ferroelectric capacitor portion, and
wherein the forming the upper electrode includes adjusting step increasing or decreasing a light reflectance on the upper electrode in accordance with the combination of the content of lead in the PZT ferroelectric substance and the film thickness of the PZT ferroelectric substance and with the residual polarization quantity of the PZT ferroelectric substance on the basis of the control of the crystallization annealing temperature and the oxygen flow rate.

20. The semiconductor device manufacturing method according to claim 19, wherein the adjusting includes, if the measured value of the residual polarization quantity is under a target value, increasing the residual polarization quantity by adjusting at least one selected from a group of consisting of a film thickness of the upper electrode, an oxygen quantity, a gas ratio and a gas flow rate of an atmosphere gas of the semiconductor substrate when forming a film, a period of sputtering time and sputtering power, and includes, if the measured value of the residual polarization quantity is above the target value, decreasing the residual polarization quantity by adjusting at least one of the film thickness of the upper electrode, the oxygen quantity, the gas ratio and the gas flow rate of then atmosphere gas of the semiconductor substrate when forming the film, the period of sputtering time and the sputtering power.
